(19) United States
(12) Patent Application Publication
(10) Pub. No.: US 2026/0239802 A1
(43) Pub. Date: Aug. 13, 2026

(54) DISPLAY DEVICE AND ELECTRONIC DEVICE

(71) Applicant: Samsung Display Co., Ltd., Yongin-si (KR)

(72) Inventors: Jong Duk ROH, Yongin-si (KR); Nak Cho CHOI, Yongin-si (KR)

(21) Appl. No.: 19/426,861

(22) Filed: Dec. 19, 2025

(30) Foreign Application Priority Data
Feb. 10, 2025 (KR) 10-2025-0016782

(51) Int. Cl. H10H 29/856; H10H 29/37; H10H 29/85; H10H 29/851; H10H 29/855

(52) U.S. Cl. CPC H10H 29/856; H10H 29/37; H10H 29/8514; H10H 29/8517; H10H 29/855

(57) ABSTRACT

A display device and an electronic device are provided. The display device includes a substrate, a transistor layer including a first transistor and a second transistor, and a sub-pixel including a first-type light-emitting element configured to be driven by the first transistor, and a second-type light-emitting element configured to be driven by the second transistor and including a first reflective pattern having a triangular shape at a lower portion of the second-type light-emitting element and including a reflective surface inclined toward a center of the lower portion.

### CROSS-REFERENCE TO RELATED APPLICATION

The present application claims priority to, and the benefit of, Korean Patent Application No. 10-2025-0016782, filed on Feb. 10, 2025, in the Korean Intellectual Property Office, the entire disclosure of which is incorporated herein by reference.

### BACKGROUND

### 1. Field

The present disclosure relates to a display device and an electronic device.

### 2. Description of the Related Art

As the information society develops, the demand for display devices for displaying images is increasing in various forms. The display devices may be flat panel displays such as liquid crystal displays, field emission displays, and light-emitting displays.

The light-emitting display devices may include organic light-emitting display device including an organic light-emitting diode element (OLED) as light-emitting element, and micro light-emitting display device including micro light-emitting diode element (hereinafter referred to as micro light-emitting element) as light-emitting element. Because the micro light-emitting diode elements is made of inorganic material, it has the aspect of having a long lifespan due to less deterioration issues compared to an organic light-emitting diode element (OLED).

The viewing angle characteristics of these display devices may be considered to be important. For example, the display devices may desirably implement clear and undistorted image quality even in a wide viewing angle range. Therefore, wide viewing angle technology is continuously being developed.

However, in addition to the wide viewing angle mode (normal mode), there is also a narrow viewing angle mode (privacy mode) for privacy, which is suitable when working on confidential documents or performing tasks that require security by allowing only the person sitting in front of the screen to see the image on the screen.

### SUMMARY

Aspects of embodiments of the present disclosure provide a display device having an effective narrow viewing angle mode, and a method for manufacturing the same in a display device providing a narrow viewing angle mode and a wide viewing angle mode.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a substrate, a transistor layer including a first transistor and a second transistor, and a sub-pixel including a first-type light-emitting element configured to be driven by the first transistor, and a second-type light-emitting element configured to be driven by the second transistor and including a first reflective pattern having a triangular shape at a lower portion of the second-type light-emitting element and including a reflective surface inclined toward a center of the lower portion.

The first reflective pattern may be provided in plural, wherein the first reflective patterns are on respective sides of the second-type light-emitting element such that the reflective surfaces face each other.

The second-type light-emitting element may include semiconductor layers, a reflective film on side and top surfaces of the semiconductor layers and defining an opening, a first protective film between the semiconductor layers and the reflective film, and a second protective film on an outside of the reflective film.

The first reflective pattern may be spaced from an area overlapping the opening.

The display device may further include a partition wall on the transistor layer and surrounding the first-type light-emitting element and the second-type light-emitting element in plan view, and at least one second reflective pattern having a triangular shape adjacent to an upper portion of the partition wall and surrounding the second-type light-emitting element in plan view.

The at least one second reflective pattern may include a first surface protruding at an angle from the partition wall, a second surface entirely in contact with the partition wall, and a third surface below the first surface and extending from the first surface to the second surface.

The angle may be about 90 degrees or more.

The second reflective pattern may be at a level that is above the second-type light-emitting element.

The partition wall may have a tapered shape that narrows in an upward direction.

The first reflective pattern and the second reflective pattern may include at least one of aluminum or silver.

The display device may further include a first optical pattern including a concave lens above the second-type light-emitting element.

The display device may further include a second optical pattern including an upwardly convex lens above the first-type light-emitting element.

The first transistor may be configured to operate in a wide viewing angle mode, wherein the second transistor is configured to operate in a narrow viewing angle mode.

The display device may further include a wavelength conversion layer in a space defined by the partition wall, and a capping layer, an overcoat layer, and a color filter layer sequentially ordered above the partition wall.

According to one or more embodiments of the present disclosure, a display device includes a substrate, a transistor layer above the substrate, a pixel electrode layer above the transistor layer, a light-emitting element above the pixel electrode layer having triangular first reflective patterns at a lower portion of the light-emitting element and inclined toward a center of the light-emitting element, and a partition wall surrounding the light-emitting element in plan view.

The light-emitting element may include semiconductor layers, a reflective film defining on side and top surfaces of the semiconductor layers and defining an opening spaced apart from the first reflective patterns in plan view, a first protective film between the semiconductor layers and the reflective film, and a second protective film on an outside of the reflective film.

The display device may further include one or more triangular second reflective patterns on one side adjacent to an upper portion of the partition wall and surrounding the light-emitting element in plan view, and including a first surface protruding at an angle from the partition wall, a second surface entirely in contact with the one side of the partition wall, and a third surface below the first surface and extending from the first surface to the second surface.

The one or more triangular second reflective patterns may be at a level above the light-emitting element.

The display device may further include an optical pattern including a concave lens above the light-emitting element.

According to one or more embodiments of the present disclosure, an electronic device includes a display panel for displaying an image and including a substrate, a transistor layer including a first transistor and a second transistor, and a sub-pixel including a first-type light-emitting element configured to be driven by the first transistor, and a second-type light-emitting element configured to be driven by the second transistor and including a first reflective pattern having a triangular shape at a lower portion of the second-type light-emitting element and including a reflective surface inclined toward a center of one surface of the second-type light-emitting element.

According to the display device and the manufacturing method thereof according to the embodiments, an effective narrow viewing angle may be provided in the display device providing a wide viewing angle mode and a narrow viewing angle mode.

However, aspects of the present disclosure are not limited to the aforementioned aspects, and various other aspects are included in the present specification.

### BRIEF DESCRIPTION OF THE DRAWINGS

FIG. 1 is a perspective view illustrating a display device according to one or more embodiments.

FIG. 2 is an enlarged view of area A of FIG. 1.

FIG. 3 is a block drawing illustrating a display device according to one or more embodiments.

FIG. 4 is a circuit diagram illustrating a first sub-pixel included in the display device of FIG. 3.

FIG. 5 is a layout diagram illustrating pixels of a display area included in the display device of FIG. 1.

FIG. 6 is a cross-sectional view taken along the line I-I′ of FIG. 5.

FIG. 7 is an enlarged view of area A1 of FIG. 6.

FIG. 8 is an enlarged view of an example of a 2-1 light-emitting element, which is a second-type light-emitting element of FIG. 7.

FIG. 9 is an enlarged view of another example of a 2-1 light-emitting element, which is a second-type light-emitting element of FIG. 7.

FIG. 10 is an enlarged view of area A1 of FIG. 6 according to one or more other embodiments.

FIG. 11 is an enlarged view of area B of FIG. 10.

FIG. 12 is an enlarged view of area B of FIG. 10 according to one or more other embodiments.

FIG. 13 is a cross-sectional view illustrating an example of a cross-section of a display panel taken along the line I-I′ of FIG. 5 according to one or more other embodiments.

FIG. 14 is a cross-sectional view illustrating an example of the A1 area of FIG. 13 in detail.

FIG. 15 is a cross-sectional view illustrating an example of the cross-section of the display panel corresponding to the line II-II′ of FIG. 5.

FIG. 16 is a cross-sectional view illustrating an example of the first-type light-emitting element of FIG. 15 in detail.

FIG. 17 is a cross-sectional view illustrating an example of the cross-section of the display panel corresponding to the line II-II′ of FIG. 5 according to one or more other embodiments.

FIG. 18 is a layout diagram illustrating pixels of the display area according to one or more embodiments.

FIG. 19 is a cross-sectional view illustrating an example of the cross-section of the display panel corresponding to the line I1-I1′ of FIG. 18.

FIG. 20 is a cross-sectional view illustrating an example of the A2 area of FIG. 19 in detail.

FIG. 21 is an enlarged view of an example of the 2-1 light-emitting element, which is the second-type light-emitting element of FIG. 20.

FIG. 22 is an enlarged view of another example of the 2-1 light-emitting element, which is the second-type light-emitting element of FIG. 20.

FIG. 23 is a cross-sectional view illustrating an example of a cross-section of a display panel taken along the line II1-II1′ of FIG. 18 according to one or more other embodiments.

FIG. 24 is a cross-sectional view illustrating in detail an example of the first-type light-emitting element of FIG. 23.

FIG. 25 is a cross-sectional view illustrating an example of a cross-section of a display panel taken along the line II1-II1′ of FIG. 18 according to one or more other embodiments.

FIG. 26 is a cross-sectional view cut along the line I-I′ of FIG. 5 according to one or more other embodiments.

FIG. 27 is an enlarged view of area B1 of FIG. 26.

FIG. 28 is a cross-sectional view illustrating an example of a cross-section of a display panel taken along the line II-II′ of FIG. 5 according to one or more other embodiments.

FIGS. 29 and 30 are drawings illustrating a smart watch including a display device according to one or more embodiments.

FIG. 31 is an exploded perspective view of a smart watch including a display device according to one or more embodiments.

FIG. 32 is an example views of a virtual reality (VR) device including a display device according to one or more embodiments.

FIG. 33 is an example view of a VR device including a display device according to one or more embodiments.

FIG. 34 is an example view illustrating a vehicle instrument cluster and center fascia including display devices according to one or more embodiments.

FIG. 35 is an example view of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

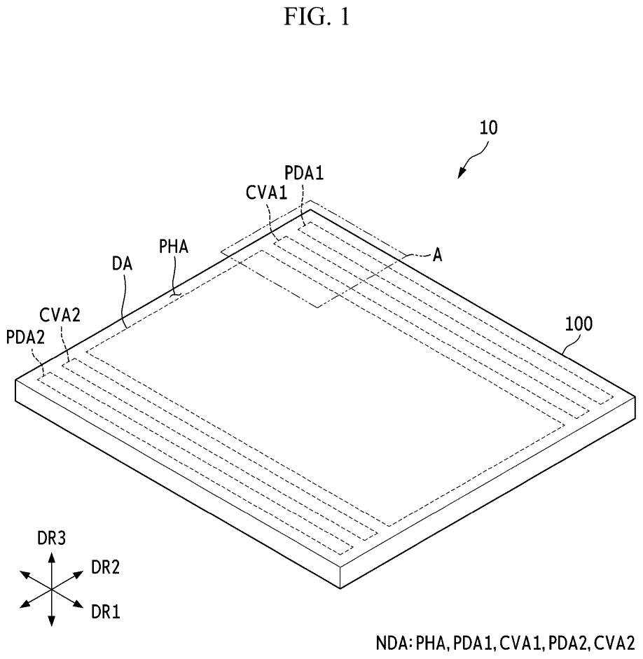

FIG. 1 is a perspective view illustrating a display device according to one or more embodiments.

Referring to FIG. 1, a display device 10 is a device for displaying video or still images, such as a mobile phone, a smart phone, a tablet personal computer (TPC), and a portable electronic device, such as a smart watch, a watch phone, a mobile communication terminal, an electronic notebook, e-books, portable electronic devices, such as portable multimedia player (PMP), navigation, and ultra mobile PC (UMPC), as well as display screens for a variety of products, including televisions, laptops, monitors, billboards, and internet of things (IOT) devices.

The display device 10 may be a light-emitting display device, such as an organic light-emitting display device using an organic light-emitting diode, a quantum dot light-emitting display device including a quantum dot light-emitting layer, an inorganic light-emitting display device including an inorganic semiconductor, and an ultra-small light-emitting display device using an ultra-small light-emitting diode (micro or nano light-emitting diode (micro LED or nano LED). Hereinafter, the display device 10 is described mainly as an ultra-small light-emitting display device, but the present disclosure is not limited thereto. An ultra-small light-emitting diode is described as a light-emitting element below for the convenience of explanation.

The display device 10 according to one or more embodiments may include a display panel 100 including a display area DA and a non-display area NDA.

The display panel 100 may have a rectangular planar shape having a long side in a first direction DR1, and a short side in a second direction DR2. However, the planar shape of the display panel 100 is not limited thereto, and the display panel 100 may have a different shape. For example, the display panel 100 may have a polygonal shape other than a rectangular shape, a circular shape, an oval shape, or an irregular flat shape.

The display area DA may be an area where an image is displayed, and the non-display area NDA may be an area where an image is not displayed. In one or more embodiments, the flat shape of the display area DA may follow the flat shape of the display panel 100. In FIG. 1, the flat shape of the display area DA is illustrated as being a rectangular shape. The display area DA may be arranged in the central area of the display panel 100. The non-display area NDA may be arranged around the display area DA. For example, the non-display area NDA may surround the display area DA.

The display area DA may include pixels PX. Each pixel PX may include at least two light-emitting elements LE.

In one or more embodiments, each pixel PX may include three light-emitting elements LE. For example, each pixel PX may include a first light-emitting element LE1, a second light-emitting element LE2, and a third light-emitting element LE3. The number and/or type of light-emitting elements LE provided to the pixels PX may vary depending on embodiments.

In one or more embodiments, each pixel PX may include light-emitting elements LE that emit light of different colors. For example, the first light-emitting element LE1, the second light-emitting element LE2, and the third light-emitting element LE3 may emit light of different respective colors.

The first light-emitting element LE1 may emit first light. The first light may be red light. For example, the main peak wavelength (R-peak) of the first light may be located at approximately 600 nm to approximately 750 nm, but embodiments are not limited thereto.

The second light-emitting element LE2 may emit second light. The second light may be green light. For example, the main peak wavelength (G-peak) of the second light may be located at approximately 480 nm to approximately 560 nm, but the embodiments are not limited thereto.

The third light-emitting element LE3 may emit third light. The third light may be blue light. For example, the main peak wavelength (B-peak) of the third light may be located at approximately 370 nm to approximately 460 nm, but the embodiments are not limited thereto.

In one or more other embodiments, the first light-emitting element LE1, the second light-emitting element LE2, and the third light-emitting element LE3 may emit light of the same color. Also, a light conversion layer including a light conversion element (e.g., a quantum dot) for converting a color (or a corresponding wavelength band) of light emitted from the at least one light-emitting element LE among the first light-emitting element LE1, the second light-emitting element LE2, and/or the third light-emitting element LE3 into light of a different color (or a corresponding wavelength band) may be arranged.

In one or more embodiments, the first light-emitting element LE1, the second light-emitting element LE2, and the third light-emitting element LE3 of each pixel PX may be sequentially arranged in the first direction DR1. In one or more embodiments, the first light-emitting elements LE1 may be arranged in the second direction DR2. The second light-emitting elements LE2 may be arranged in the second direction DR2. The third light-emitting elements LE3 may be arranged in the second direction DR2. For example, in each pixel column extending along the second direction DR2, the first light-emitting element LE1, the second light-emitting element LE2, or the third light-emitting element LE3 may be arranged. Further, the arrangement structure of the pixels PX and the light-emitting elements LE provided to the pixels PX may be variously changed according to embodiments.

In one or more embodiments, the light-emitting elements LE may be arranged in the display area DA at substantially the same interval but is not limited thereto. For example, the positions and/or the arrangement intervals of the light-emitting elements LE may be variously changed according to embodiments.

In one or more embodiments, the sizes (e.g., areas) of the light-emitting elements LE may be substantially the same. For example, the first light-emitting element LE1, the second light-emitting element LE2, and the third light-emitting element LE3 may have substantially the same size. However, the embodiments are not limited thereto, and the size of each of the light-emitting elements LE, and/or the area of the light-emitting areas corresponding to the light-emitting elements LE, etc. may be variously changed according to the embodiments.

In one or more embodiments, the light-emitting elements LE may have a circular planar shape, but the embodiments are not limited thereto. For example, the light-emitting elements LE may have a rectangular shape or other polygonal, oval, or irregular shape. In addition, the light-emitting elements LE may have substantially the same planar shape or may have different planar shapes for each group.

The non-display area NDA may include a first common voltage supply area CVA1, a second common voltage supply area CVA2, a first pad area PDA1, a second pad area PDA2, and a peripheral area PHA.

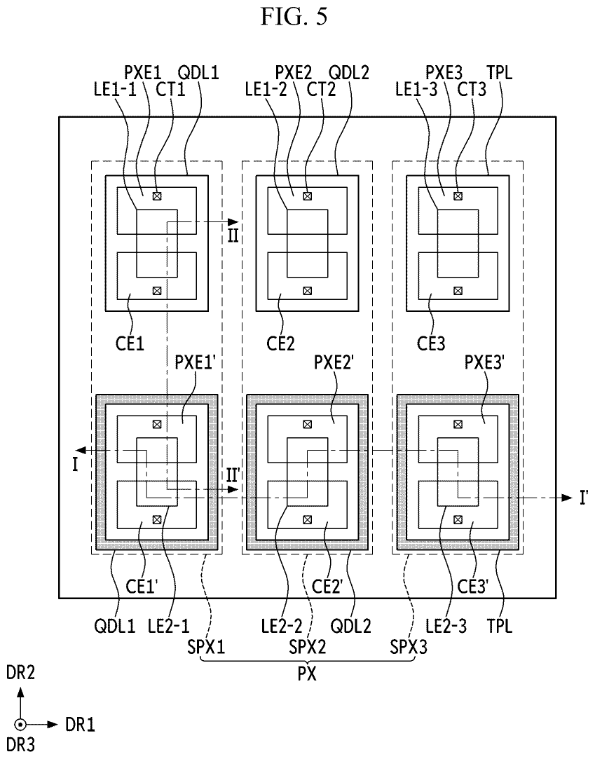

The first common voltage supply area CVA1 may be arranged between the first pad area PDA1 and the display area DA. The second common voltage supply area CVA2 may be arranged between the second pad area PDA2 and the display area DA. Each of the first common voltage supply area CVA1 and the second common voltage supply area CVA2 may include common electrode connectors CVS connected to a common electrode (e.g., the common electrodes CE1, CE2, and CE3 in FIG. 5). For example, the common electrode may extend from the display area DA to the first common voltage supply area CVA1 and the second common voltage supply area CVA2 and be electrically connected to the common electrode connectors CVS. The common voltage may be supplied to the common electrode through the common electrode connectors CVS.

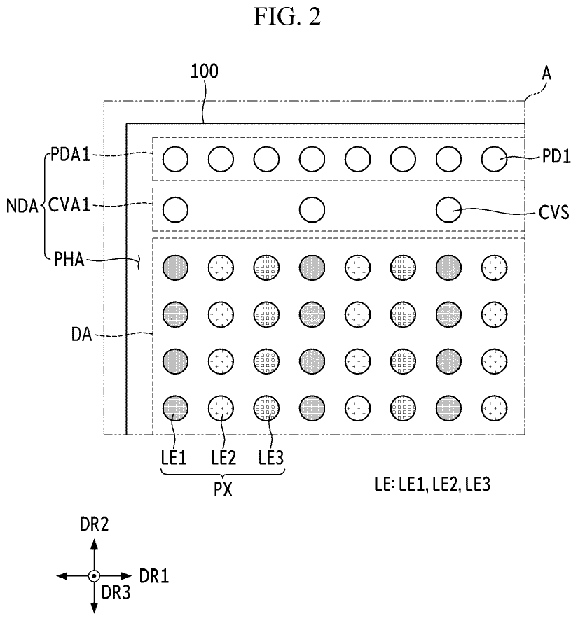

The common electrode connectors CVS may be arranged in the common voltage supply area (e.g., the first common voltage supply area CVA1 and/or the second common voltage supply area CVA2) of the non-display area NDA. The common electrode connectors CVS may include a conductive material (e.g., a metal material, such as aluminum (Al)). Although FIGS. 1 and 2 illustrate a display device 10 in which the common electrode connectors CVS are positioned in the non-display area NDA, the embodiments are not limited thereto. For example, the common electrode connectors CVS may be arranged in the display area DA. In one example, the common electrode connectors CVS may be positioned in the pixel areas or between the pixel areas.

The common electrode connectors CVS of the first common voltage supply area CVA1 may be electrically connected to one of the first pads PD1 of the first pad area PDA1. For example, the common electrode connectors CVS of the first common voltage supply area CVA1 may receive a common voltage from one of the first pads PD1 of the first pad area PDA1.

The first pads PD1 may be arranged in the first pad area PDA1. In one or more embodiments, the first pads PD1 may be connected to a circuit board through a conductive connection member. For example, the first pads PD1 may be electrically connected to a circuit pad provided on the circuit board through a wire.

The common electrode connections CVS of the second common voltage supply area CVA2 may be electrically connected to one of the second pads of the second pad area PDA2. For example, the common electrode connections CVS of the second common voltage supply area CVA2 may receive a common voltage from one of the second pads of the second pad area PDA2. In one or more embodiments, the display panel 100 may not include the second common voltage supply area CVA2.

The first pad area PDA1 may be arranged on one side (e.g., a top side) of the display panel 100. The first pad area PDA1 may include first pads PD1 connected to an external circuit board.

The second pad area PDA2 may be arranged on another side (e.g., a bottom side) of the display panel 100. The second pad area PDA2 may include second pads connected to an external circuit board. In one or more embodiments, the display panel 100 may not include the second pad area PDA2.

The second pads may be arranged in the second pad area PDA2 of the non-display area NDA. In one or more embodiments, the second pads may be connected to a circuit board through a conductive connection member. For example, the second pads may be electrically connected to a circuit pad provided on the circuit board through a wire.

The peripheral area PHA may be a remaining area in the non-display area NDA except for the first common voltage supply area CVA1, the second common voltage supply area CVA2, the first pad area PDA1, and the second pad area PDA2. The peripheral area PHA may surround not only the display area DA, but also the first common voltage supply area CVA1, the second common voltage supply area CVA2, the first pad area PDA1, and the second pad area PDA2.

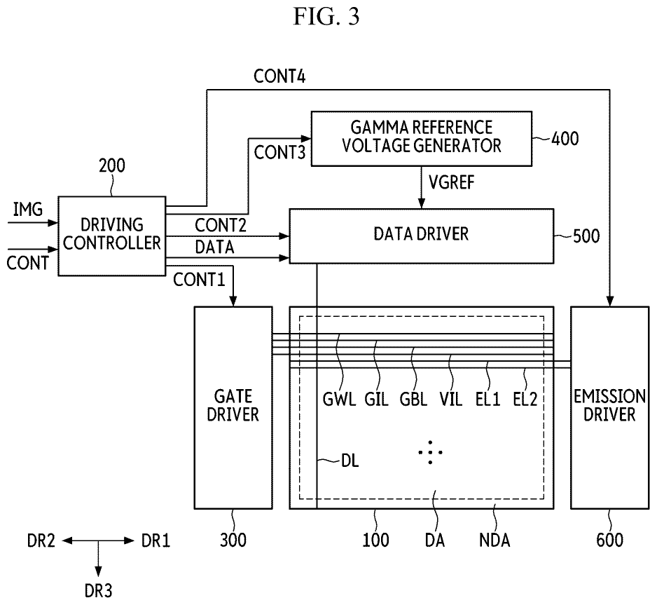

FIG. 3 is a block drawing illustrating a display device according to one or more embodiments.

Referring to FIG. 3, a display device according to one or more embodiments of the present disclosure may include a display panel 100 and a display panel-driving portion. The display panel-driving portion may include a driving control portion 200, a gate-driving portion 300, a gamma reference voltage generation portion 400, a data driving portion 500, and a light-emission-driving portion 600.

The display panel 100 may include a display area DA for displaying an image and a non-display area NDA located around the display area DA.

The display panel 100 may include a plurality of gate lines GWL, GIL, and GBL, a plurality of data lines DL, a plurality of first light-emitting control lines EL1, a plurality of second light-emitting control lines EL2, and a plurality of sub-pixels. The sub-pixels may be electrically connected to each of the plurality of gate lines GWL, GIL, and GBL, the plurality of data lines DL, the plurality of first light-emitting control lines EL1, and the plurality of second light-emitting control lines EL2. For example, each of the plurality of gate lines GWL, GIL, and GBL, the plurality of first light-emitting control lines EL1, and the plurality of second light-emitting control lines EL2 may extend in a first direction DR1 or a second direction DR2 opposite to the first direction DR1. Each of the plurality of data lines DL may extend in a third direction DR3 intersecting the first direction DR1 and the second direction DR2.

The display panel 100 may further include initialization lines VIL that transmit an initialization voltage to the sub-pixels. For example, each of the initialization lines VIL may extend in the first direction DR1 or the second direction DR2.

The driving control portion 200 may receive input image data IMG and an input control signal CONT from an external device, in one or more embodiments. For example, the input image data IMG may include red image data, green image data, and blue image data. The input image data IMG may include white image data. The input image data IMG may include magenta image data, yellow image data, and cyan image data. The input control signal CONT may include a master clock signal and a data enable signal. The input control signal CONT may further include a vertical synchronization signal and a horizontal synchronization signal.

The driving control portion 200 may generate a first control signal CONT1, a second control signal CONT2, a third control signal CONT3, a fourth control signal CONT4, and a data signal DATA based on the input image data IMG and the input control signal CONT.

The driving control portion 200 may generate a first control signal CONT1 for controlling the operation of the gate-driving portion 300 based on the input control signal CONT. The driving control portion 200 may output a first control signal CONT1 to the gate-driving portion 300. The first control signal CONT1 may include a vertical start signal and a gate clock signal.

The driving control portion 200 may generate a second control signal CONT2 for controlling the operation of the data driving portion 500 based on the input control signal CONT. The driving control portion 200 may output the second control signal CONT2 to the data driving portion 500. The second control signal CONT2 may include a horizontal start signal and a load signal.

The driving control portion 200 may generate a data signal DATA based on the input image data IMG. The driving control portion 200 may output the data signal DATA to the data driving portion 500.

The driving control portion 200 may generate the third control signal CONT3 for controlling the operation of the gamma reference voltage generation portion 400 based on the input control signal CONT. The driving control portion 200 may output the third control signal COTN3 to the gamma reference voltage generation portion 400.

The driving control portion 200 may generate the fourth control signal CONT4 for controlling the operation of the light-emission-driving portion 600 based on the input control signal CONT. The driving control portion 200 may output the fourth control signal CONT4 to the light-emission-driving portion 600.

The gate-driving portion 300 may generate gate signals for driving a plurality of gate lines GWL, GIL, and GBL in response to the first control signal CONT1 received from the driving control portion 200. The gate-driving portion 300 may output the gate signals to a plurality of gate lines GWL, GIL, and GBL.

The gate-driving portion 300 may generate initialization voltages for driving a plurality of initialization lines VIL in response to a first control signal CONT1 input from the driving control portion 200. The gate-driving portion 300 may output the initialization voltages to a plurality of initialization lines VIL.

The gamma reference voltage generation portion 400 may generate a gamma reference voltage VGREF in response to a third control signal CONT3 input from the driving control portion 200. The gamma reference voltage generation portion 400 may provide the gamma reference voltage VGREF to the data driving portion 500. The gamma reference voltage VGREF may have a value corresponding to each data signal DATA.

For example, the gamma reference voltage generation portion 400 may be arranged in the driving control portion 200 or in the data driving portion 500.

The data driving portion 500 may receive a second control signal CONT2 and a data signal DATA from the driving control portion 200 and may receive a gamma reference voltage VGREF from the gamma reference voltage generation portion 400. The data driving portion 500 may convert the data signal DATA into an analog data voltage using the gamma reference voltage VGREF. The data driving portion 500 may output the data voltage to a plurality of data lines DL.

The light-emission-driving portion 600 may generate light-emitting control signals for driving the first and second light-emitting control lines EL1 and EL2 in response to the fourth control signal CONT4 received from the driving control portion 200. The light-emission-driving portion 600 may output the light-emitting control signals to the first and second light-emitting control lines EL1 and EL2.

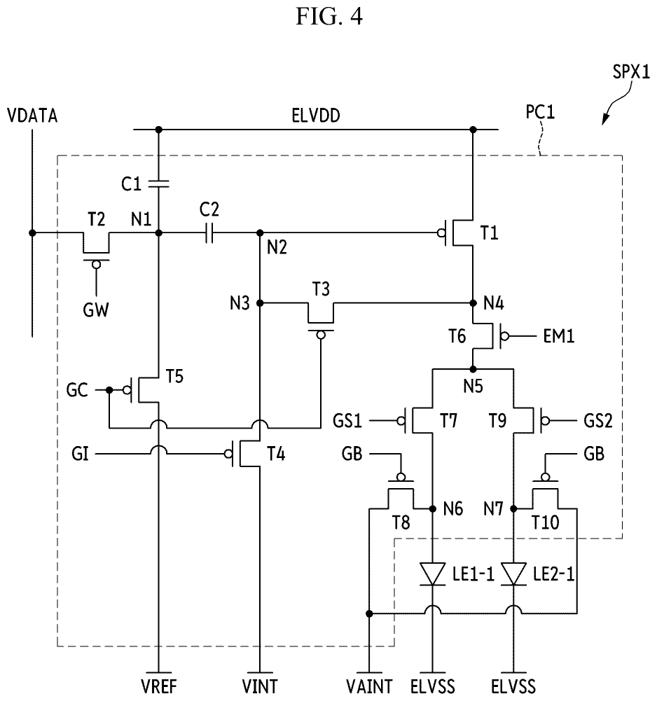

FIG. 4 is a circuit diagram illustrating a first sub-pixel included in the display device of FIG. 3.

Referring to FIGS. 3 and 4, the first sub-pixel SPX1 included in the display panel 100 may include a first pixel circuit PC1, a 1-1 light-emitting element LE1-1, and a 2-1 light-emitting element LE2-1. The first pixel circuit PC1 may provide a first driving current to the 1-1 light-emitting element LE1-1 and the 2-1 light-emitting element LE2-1. The 1-1 light-emitting element LE1-1 and the 2-1 light-emitting element LE2-1 may emit light of the same color based on the first driving current.

Each of the first pixel circuits PC1 may include first to tenth transistors T1, T2, T3, T4, T5, T6, T7, T8, T9, and T10, a first capacitor C1, and a second capacitor C2.

The first transistor T1 may include a gate electrode, a first electrode, and a second electrode. The gate electrode of the first transistor T1 may be connected to a second node N2. A driving voltage ELVDD may be applied to the first electrode of the first transistor T1. The second electrode of the first transistor T1 may be connected to a fourth node N4.

The second transistor T2 may include a gate electrode, a first electrode, and a second electrode. A first gate signal GW may be applied to the gate electrode of the second transistor T2. A data voltage VDATA may be applied to the first electrode of the second transistor T2. The second electrode of the second transistor T2 may be connected to the first node.

The third transistor T3 may include a gate electrode, a first electrode, and a second electrode. A second gate signal GC may be applied to the gate electrode of the third transistor T3. The first electrode of the third transistor T3 may be connected to the third node N3. The second electrode of the third transistor T3 may be connected to the fourth node N4.

The fourth transistor T4 may include a gate electrode, a first electrode, and a second electrode. A third gate signal GI may be applied to the gate electrode of the fourth transistor T4. A first initialization voltage VINT may be applied to the first electrode of the fourth transistor T4. A second electrode of the fourth transistor T4 may be connected to the third node N3.

The fifth transistor T5 may include a gate electrode, a first electrode, and a second electrode. A second gate signal GC may be applied to the gate electrode of the fifth transistor T5. A reference voltage VREF may be applied to the first electrode of the fifth transistor T5. The second electrode of the fifth transistor T5 may be connected to the first node N1.

The sixth transistor T6 may include a gate electrode, a first electrode, and a second electrode. The first electrode of the sixth transistor T6 may be connected to the fifth node N5. The second electrode of the sixth transistor T6 may be connected to the fourth node N4. In one or more embodiments, in the first pixel circuits PC1, the first light-emitting control signal EM1 may be applied to the gate electrode of the sixth transistor T6.

The seventh transistor T7 may include a gate electrode, a first electrode, and a second electrode. The fourth gate signal GS1 may be applied to the gate electrode of the seventh transistor T7. The first electrode of the seventh transistor T7 may be connected to the sixth node N6. The second electrode of the seventh transistor T7 may be connected to the fifth node N5.

The eighth transistor T8 may include a gate electrode, a first electrode, and a second electrode. The first electrode of the eighth transistor T8 may be applied with a second initialization voltage VAINT. The second electrode of the eighth transistor T8 may be connected to a sixth node N6. The second electrode of the eighth transistor T8 may be connected to a sixth node N6. In one or more embodiments, in the first pixel circuit PC1, a fifth gate signal GB may be applied to the gate electrode of the eighth transistor T8.

The ninth transistor T9 may include a gate electrode, a first electrode, and a second electrode. A sixth gate signal GS2 may be applied to the gate electrode of the ninth transistor T9. The first electrode of the ninth transistor T9 may be connected to the seventh node N7, and the second electrode may be connected to the fifth node N5.

The tenth transistor T10 may include a gate electrode, a first electrode, and a second electrode. The fifth gate signal GB may be applied to the gate electrode of the tenth transistor T10. A second initialization voltage VAINT may be applied to the first electrode of the tenth transistor T10. The second electrode of the tenth transistor T10 may be connected to the seventh node N7.

The first capacitor C1 may include a first electrode and a second electrode. A driving voltage ELVDD may be applied to the first electrode of the first capacitor C1. The second electrode of the first capacitor C1 may be connected to the first node N1. In one or more embodiments, the first capacitor C1 may be a storage capacitor.

The second capacitor C2 may include a first electrode and a second electrode. The first electrode of the second capacitor C2 may be connected to the first node N1. The second electrode of the second capacitor C2 may be connected to the second node N2. In one or more embodiments, the second capacitor C2 may be a hold capacitor.

Each of the 1-1 light-emitting element LE1-1 and the 2-1 light-emitting element LE2-1 may include a first electrode (e.g., a pixel electrode) and a second electrode (e.g., a common electrode). The first electrode of the 1-1 light-emitting element LE1-1 may be connected to the sixth node. A common voltage ELVSS may be applied to the second electrode of each of the 1-1 light-emitting elements LE1-1. In one or more embodiments, the 1-1 light-emitting element LE1-1 may be controlled by the fourth gate signal GS1.

The 2-1 light-emitting element LE2-1 may include a first electrode (e.g., a pixel electrode) and a second electrode (e.g., a common electrode). The first electrode of the 2-1 light-emitting element LE2-1 may be connected to the seventh node N7. A common voltage ELVSS may be applied to the second electrode of the 2-1 light-emitting element LE2-1. In one or more embodiments, the 2-1 light-emitting element LE2-1 may be controlled by the sixth gate signal GS2.

For example, when the first light-emitting control signal EM1 has an activation level and the fourth gate signal GS1 has an activation level, the seventh transistor T7 and the eighth transistor T8 may be turned on. Further, the first transistor T1 may also be turned on by the data voltage VDATA. In this case, in the first pixel circuit PC1, the first driving current may drive the 1-1 light-emitting element LE1-1 through the first transistor T1.

On the other hand, for example, when the first light-emitting control signal EM1 has an activation level and the sixth gate signal GS2 has an activation level, the ninth transistor T9 and the tenth transistor T10 may be turned on. Further, the first transistor T1 may also be turned on by the data voltage VDATA. In this case, in the first pixel circuit PC1, the first driving current may drive the 2-1 light-emitting element LE2-1 through the first transistor T1.

For example, each of the first to tenth transistors T1, T2, T3, T4, T5, T6, T7, T8, T9, and T10 may be a P-type thin film transistor. Embodiments of the present disclosure are not limited thereto.

However, in FIG. 4, each of the first sub-pixels SPX1 is illustrated as including ten transistors, two capacitors, and two light-emitting elements, but embodiments of the present disclosure are not limited thereto.

FIG. 5 is a layout diagram illustrating pixels of a display area included in the display device of FIG. 1.

Referring to FIG. 5, each of the plurality of pixels PX of the display area DA may include three sub-pixels SPX1, SPX2, and SPX3, but the embodiment of the present disclosure is not limited thereto and may include four sub-pixels. When each of the plurality of pixels PX includes three sub-pixels SPX1, SPX2, and SPX3, it may include a first sub-pixel SPX1, a second sub-pixel SPX2, and a third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. The light of the first color may be light in a blue wavelength band, the light of the second color may be light in a green wavelength band, and the light of the third color may be light in a red wavelength band. For example, the blue wavelength band may refer to light having a main peak wavelength in the wavelength band from approximately 370 μm to approximately 460 μm, the green wavelength band may refer to light having a main peak wavelength in the wavelength band from approximately 480 μm to approximately 560 μm, and the red wavelength band may refer to light having a main peak wavelength in the wavelength band from approximately 600 μm to approximately 750 μm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the light of the fourth color may be white light.

Each of the sub-pixels SPX1, SPX2, and SPX3 may include a first-type light-emitting element LE1-1, LE1-2, and LE1-3 and a second-type light-emitting element LE2-1, LE2-2, and LE2-3. For example, the first sub-pixel SPX1 may include a 1-1 light-emitting element LE1-1 that is a first-type light-emitting element and a 2-1 light-emitting element LE2-1 which is a second-type light-emitting element, the second sub-pixel SPX2 may include a 1-2 light-emitting element LE1-2 that is a first-type light-emitting element and a 2-2 light-emitting element LE2-2 that is a second-type light-emitting element, and the third sub-pixel SPX3 may include a 1-3 light-emitting element LE1-3 that is a first-type light-emitting element and a 2-3 light-emitting element LE2-3 that is a second-type light-emitting element.

The first-type light-emitting element is an element for implementing a wide viewing angle mode or a shared mode (normal mode), and the second-type light-emitting element is an element for implementing a narrow viewing angle mode or a privacy mode. A detailed description thereof will be provided later.

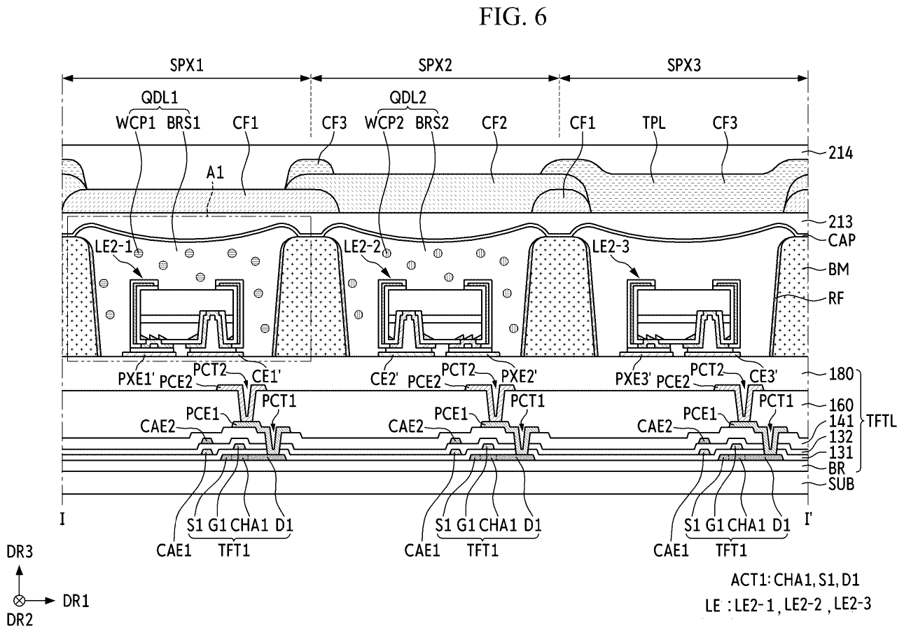

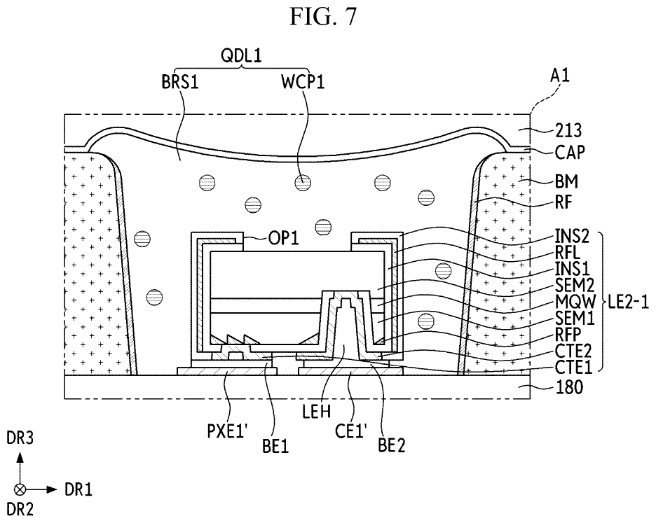

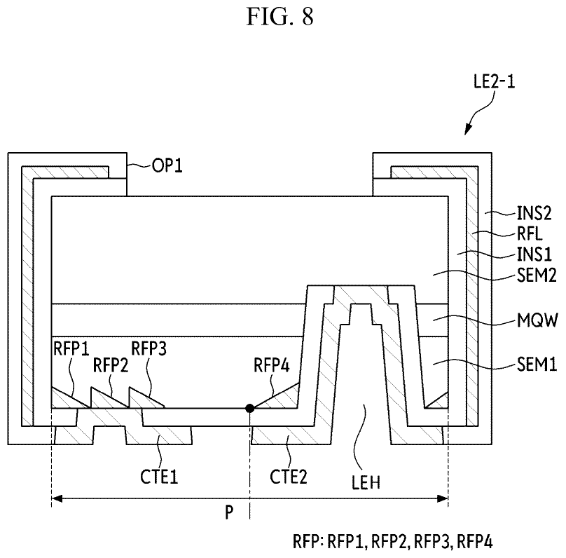

FIG. 6 is a cross-sectional view taken along the line I-I′ of FIG. 5. FIG. 7 is an enlarged view of area A1 of FIG. 6. FIG. 8 is an enlarged view of an example of a 2-1 light-emitting element, which is a second-type light-emitting element of FIG. 7.

Referring to FIGS. 6 to 7, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be arranged on the substrate SUB. The barrier film BR is a film that protects the transistors of the thin film transistor layer TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may include a first active layer ACT1 and a first gate electrode G1. The thin film transistor TFT1 connected to the first-type light-emitting element LE1 may be the eighth transistor T8 of FIG. 4. The eighth transistor T8 may turn on the first-type light-emitting element LE1 in a wide viewing angle mode.

In addition, the thin film transistor TFT1 connected to the second-type light-emitting element LE2 may be the tenth transistor T10 of FIG. 4. The tenth transistor T10 may turn on the second-type light-emitting element LE2 in a narrow viewing angle mode.

The first active layer ACT1 of the thin film transistor TFT1 may be arranged on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate-insulating film 131 may be arranged on the first channel area CHA1, the first source area S1, and the first drain area D1 of the thin film transistor TFT1.

A first gate metal layer may be arranged on the first gate-insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart from each other in FIG. 6, the first gate electrode G1 and the first capacitor electrode CAE1 may be connected to each other.

A second gate-insulating film 132 may be arranged on the first gate electrode G1 and the first capacitor electrode CAE1 of the thin film transistor TFT1.

A second gate metal layer may be arranged on the second gate-insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate-insulating film 132 has a dielectric constant (e.g., predetermined dielectric constant), the capacitor (C1 in FIG. 4) may be formed by the first capacitor electrode CAE1, the second capacitor electrode CAE2, and the second gate-insulating film 132 arranged between them.

An interlayer insulating film 141 may be arranged on the second capacitor electrode CAE2.

A first data metal layer may be arranged on the interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate-insulating film 131, the second gate-insulating film 132, and the interlayer insulating film 141.

A first planarization organic film 160 may be arranged on the first source connection electrode PCE1 to planarize a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2.

The barrier film BR, the first gate-insulating film 131, the second gate-insulating film 132, the third gate-insulating film 133, and the interlayer insulating film 141 may be formed of an inorganic film, such as silicon nitride (SiNₓ), silicon oxide nitride (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

The first planarization organic film 160 and the second planarization organic film 180 may be formed of an organic film, such as an acrylic resin, an epoxy resin, a phenolic resin, a polyamide resin, a polyimide resin, or the like.

A light-emitting element layer may be arranged on the second planarization organic film 180. The light-emitting element layer may include pixel electrodes PXE1, PXE2, and PXE3, light-emitting elements LE, and common electrode CE1, CE2, and CE3.

A pixel electrode layer including pixel electrodes PXE1, PXE2, and PXE3 and common electrodes CE1, CE2, and CE3 may be arranged on a second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a wire to which a common voltage (ELVSS in FIG. 4) is applied through a common connection hole (CT4/CT5/CT6 in FIG. 5). Therefore, the common voltage (ELVSS in FIG. 4) may be applied to each of the common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), or copper (Cu), or alloys thereof. For example, the pixel electrode layer may be made of copper (Cu) having low surface resistance to lower the resistance of each of the pixel electrodes PXE1, PXE2, and PXE3.

A plurality of light-emitting elements LE may be arranged on each pixel electrode layer. In FIGS. 6 and 7, the light-emitting elements LE are shown as flip-type micro LED. The flip-type micro LED refers to an LED in which contact electrodes CTE1 and CTE2 are formed on one surface (e.g., a bottom surface) of the light-emitting element LE.

Each of the plurality of light-emitting elements LE may be formed from an inorganic material, such as gallium nitride (GaN).

Each of the plurality of light-emitting elements LE may be formed by growing on a semiconductor substrate, such as a silicon substrate or a sapphire substrate. The plurality of light-emitting elements LE may be transferred onto the pixel electrode layer of the display panel 100 directly from the semiconductor substrate or through a relay substrate. Alternatively, the plurality of light-emitting elements LE may be transferred onto the pixel electrodes PXE1, PXE2, and PXE3 of the display panel 100 by an electrostatic method using an electrostatic head or a stamp method using an elastic polymer material, such as PDMS (polydimethylsiloxane) or silicon as a transfer substrate.

In one or more embodiments, a reflective layer may be arranged on the top surface of the pixel electrode PXE1 and the common electrode CE1.

The reflective film may reflect light traveling downward from the light-emitting element LE and emit light to the top surface of the light-emitting element LE. Therefore, because the light loss of the light-emitting element LE may be reduced, the light efficiency of the light-emitting element LE may be increased.

The reflective film may be formed as a single layer of a metal having high reflectivity or may be formed as a multilayer, such as titanium (Ti)/aluminum (Al)/titanium (Ti) or ITO/aluminum (Al)/ITO. Further, the reflective film may be formed as a double structure of organic films having different refractive indices. In this case, the organic film having a lower refractive index may be arranged closer to the light-emitting element LE, and the organic film having a higher refractive index may be arranged further away from the light-emitting element LE.

Referring to FIG. 8 in consideration of FIGS. 6 and 7, the light-emitting element LE may include a first semiconductor layer SEM1, an active layer MQW, a second semiconductor layer SEM2, a third semiconductor layer SEM3, a first contact electrode CTE1, a second contact electrode CTE2, a first protective film (e.g., first protective layer) INS1, a first reflective film RFL, a reflective pattern RFP (e.g., a first reflective pattern, in the claims), and a second protective film (e.g., second protective layer) INS2.

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), or the like, such as gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group three to five semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt% to approximately 20 wt%.

The second semiconductor layer SEM2 may be arranged on the active layer MQW. The second semiconductor layer SEM2 may be a semiconductor material layer doped with a second conductive dopant, such as silicon (Si), germanium (Ge), tin (Sn), or the like, for example, gallium nitride (GaN).

An electron-blocking layer may be arranged between the first semiconductor layer SEM1 and the active layer MQW. The electron-blocking layer may be a layer to suppress, reduce, or prevent too many electrons from flowing into the active layer MQW. For example, the electron-blocking layer may be aluminum gallium nitride (AlGaN) or p-type aluminum gallium nitride (AlGaN) doped with p-type magnesium (Mg). The electron-blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The first protective film INS1 may be a film for protecting the bottom surface and the side surface of the light-emitting element LE and reducing or preventing contact between the first reflective film RFL and the semiconductor layers. Therefore, the first protective film INS1 may be formed of an inorganic film, such as an insulating film of silicon nitride (SiNₓ), silicon oxide nitride (SiON), silicon oxide (SiOₓ), titanium oxide (TiOₓ), or aluminum oxide (AlOₓ).

The first protective film INS1 may be arranged on the bottom surface and the side surface of the first semiconductor layer SEM1 and the side surfaces of the plurality of semiconductor layers SEM1, MQW, SEM2, and SEM3. Further, the first protective film INS1 may be arranged on the top surface of the second semiconductor layer SEM2 except for an opening OP-1 exposing a portion of the top surface of the light-emitting element LE, for example, the top surface of the second semiconductor layer SEM2.

A hole LEH may be formed to expose a second semiconductor layer SEM2 by penetrating a first semiconductor layer SEM1 of the light-emitting element LE and the active layer MQW. The hole LEH may have a rectangular planar shape, but the embodiment of the present disclosure is not limited thereto. For example, the hole LEH may have a polygonal, circular, and elliptical planar shape, such as a square.

In addition, a first protective film INS1 may be arranged on a sidewall of the first semiconductor layer SEM1 exposed by the hole LEH and a sidewall of the active layer MQW. The first protective film INS1 may not cover the second semiconductor layer SEM2 in the hole LEH. Therefore, the second semiconductor layer SEM2 may be exposed without being covered by the first protective film INS1.

The first reflective film RFL may surround the side of the light-emitting element LE and cover a portion of the top surface of the light-emitting element LE. The first reflective film RFL may have an opening that overlaps (e.g., in plan view) the first opening OP1 defined by the first protective film INS1. Therefore, the first reflective film RFL may be arranged on the top surface of the light-emitting element LE except for the first opening OP1. The upper surface of the second semiconductor layer SEM2 may still be exposed by the first opening OP1. The first opening OP1 includes the center of the light-emitting element LE and may be arranged in the center region of the top surface of the light-emitting element LE but is not limited thereto.

As the opening OP1 of the first reflective film RFL becomes narrower, the straightness of the light-emitting element LE may increase. However, because the light emission efficiency may decrease as the opening OP1 of the first reflective film RFL becomes narrower, the area of the opening OP1 should be designed considering the straightness and light emission efficiency of the light-emitting element LE.

The first reflective film RFL may include a metal material having a high reflectivity. For example, the first reflective film RFL may include aluminum or silver, and may also include an alloy thereof.

Alternatively, the first reflective film RFL may include a first layer and a second layer of M pairs (M is an integer greater than or equal to 2) having different refractive indices to function as distributed Bragg reflectors (DBR). In this case, the M first layers and the M second layers may be arranged alternately. The first layer and the second layer may be formed of an inorganic film, such as silicon nitride (SiNₓ), silicon oxide nitride (SiON), silicon oxide (SiOₓ), titanium oxide (TiOₓ), or aluminum oxide (AlOₓ).

The second protective film INS2 reduces or prevents electrical connection between the first reflective film RFL and other components, and serves to protect the first reflective film RFL. The second protective film INS2 is arranged on the outer surface of the first reflective film RFL on the side surface of the light-emitting element LE and at least a portion of the top surface of the light-emitting element LE. Therefore, the first reflective film RFL is not electrically connected to the semiconductor layer of the light-emitting element LE and the contact electrodes CTE1 and CTE2 by the second protective film INS2.

The reflective pattern RFP is arranged between the contact electrode of the light-emitting element LE and the first semiconductor layer SME1 and serves to change the path of light incident on the reflective pattern RFP.

The light incident on the reflective pattern RFP may include light emitted downwardly from the lower light-emitting element LE, or light emitted from the side of the light-emitting element LE and reflected downwardly from the light-emitting element LE by the first reflective film RFL of the light-emitting element LE.

The reflective pattern RFP may be formed from a plurality of triangular shapes (e.g., triangular in a cross section). The cross-section of the reflective pattern RFP may be formed in at least one triangular shape among a right triangle, an equilateral triangle, or an isosceles triangle. The hypotenuse of each triangular mountain of the reflective pattern RFP may be a reflective surface. The hypotenuse of each triangular mountain of the reflective pattern RFP has a slope (e.g., predetermined slope) toward (e.g., generally toward, or in a direction that is toward) the center P of the bottom surface of the light-emitting element LE, for example, one surface of the first semiconductor layer SEM1. Furthermore, because the opening OP1 overlaps the center P, the hypotenuse of the triangle may be inclined toward the opening OP1 (as used herein, the term “hypotenuse” may refer more generally to a side of a triangle that is opposite the corner or angle of the triangle that is largest of, or one of the largest of, the three corners/angles, even if the largest angle/corner is not 90 degrees). The hypotenuses of the patterns arranged on both sides of the center P of one side may be arranged to face each other (e.g., may face upwardly and toward each other). For example, the reflective pattern RFP may include a first pattern RFP1, a second pattern RFP2, and a third pattern RFP3 arranged on the left side of the center P of one side, and a fourth pattern RFP4 arranged on the right side of the center P. The first pattern RFP1, the second pattern RFP2, and the third pattern RFP3 may be arranged sequentially from the outside toward the center P. The hypotenuses of the third pattern RFP3 and the fourth pattern RFP4 may face each other.

The reflective pattern RFP may be formed of a metal material having a high reflectivity, such as aluminum (Al), like a reflective film, but is not limited thereto. The reflective pattern RFP may change the path of light by using the refractive index. For example, a reflection effect may be achieved by forming it with an organic material having a low refractive index. The organic material may include acrylic resin, epoxy resin, phenolic resin, polyamide resin, polyimide resin, and the like.

The hypotenuse surfaces of the reflective patterns RFP arranged on respective sides of the center of one side of the first semiconductor layer SEM1 of the light-emitting element LE may be arranged to face each other.

The reflective pattern RFP may not be arranged in, or may be omitted from, an area overlapping the opening OP1.

The first contact electrode CTE1 and the second contact electrode CTE2 may be arranged on the bottom surface of the semiconductor layer, for example, one side of the first semiconductor layer SEM1 (as used herein, “arranged on” may mean “below,” “adjacent a side of,” and/or “above”). The first contact electrode CTE1 may be arranged on the bottom surface of the first semiconductor layer SEM1 that is exposed and not covered by the protective film INS. Therefore, the first contact electrode CTE1 may be electrically connected to the first semiconductor layer SEM1.

The second contact electrode CTE2 may be arranged on at least one side of the first semiconductor layer SEM1 and on at least one side and the bottom surface of the conductive layer E1. At this time, the first contact electrode CTE1 may be arranged on the first side of the semiconductor stack STC and the first side of the conductive layer E1, while the second contact electrode CTE2 may be arranged on the second side of the semiconductor stack STC and the second side of the conductive layer E1.

The second contact electrode CTE2 may be arranged on the first protective film INS1 arranged in the hole LEH and the second semiconductor layer SEM2 exposed in the hole LEH while not being covered by the protective film INS1. Therefore, the second contact electrode CTE2 may be electrically connected to the second semiconductor layer SEM2 in the hole LEH.

The first contact electrode CTE1 and the second contact electrode CTE2 may be arranged on at least a portion of the side surfaces of the plurality of semiconductor layers SEM1, MQW, and SEM2. The first contact electrode CTE1 and the second contact electrode CTE2 are spaced apart from the top surface of the light-emitting element LE in the third direction DR3. For example, among the sides of the plurality of semiconductor layers SEM1, MQW, SEM2, and SEM3, at least an area adjacent to the top surface of the third semiconductor layer SEM3 may be exposed without being covered by the first contact electrode CTE1 and the second contact electrode CTE2. The first contact electrode CTE1 and the second contact electrode CTE2 may be formed lower than at least one end of the protective film INS.

The first contact electrode CTE1 and the second contact electrode CTE2 may include one of molybdenum (Mo), aluminum (Al), chromium (Cr), gold (Au), titanium (Ti), nickel (Ni), neodymium (Nd), or copper (Cu). For example, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of the first contact electrode CTE1 and the second contact electrode CTE2 may be arranged on three side surfaces of the plurality of semiconductor layers SEM1, MQW, SEM2, and SEM3. For example, when the plurality of semiconductor layers SEM1, MQW, SEM2, and SEM3 include the first to fourth side surfaces, the first contact electrode CTE1 may be arranged on the first side surface, the second side surface, and the third side surface, and the second contact electrode CTE2 may be arranged on the second side surface, the third side surface, and the fourth side surface.

A first bonding electrode BE1 and a second bonding electrode BE2 may be arranged between the contact electrodes CTE1 and CTE2 of the light-emitting element LE and the pixel electrode layer. For example, the first bonding electrode BE1 may be arranged between the pixel electrode PXE1 and the first contact electrode CTE1, and the second bonding electrode BE2 may be arranged between the common electrode CE1 and the second contact electrode CTE2. The first bonding electrode BE1 and the second bonding electrode BE2 serve as bonding metals that bond the light-emitting element LE to the pixel electrode PXE1 and the common electrode CE1. The first bonding electrode BE1 and the second bonding electrode BE2 can include any one of molybdenum (Mo), aluminum (Al), chromium (Cr), gold (Au), titanium (Ti), nickel (Ni), neodymium (Nd), or copper (Cu).

On the second planarization organic film 180, a partition wall BM may be further arranged to compartmentalize each sub-pixel SPX1, SPX2, and SPX3.

The partition wall BM also be referred to as a light-blocking layer in that it includes a light-blocking material to reduce or prevent light from a light-emitting element LE of a sub-pixel from proceeding to an adjacent sub-pixel.

The partition wall BM may be formed in a grid-shaped pattern on a plane over the entire display area DA. The partition wall BM may not overlap with a plurality of light-emitting elements LE in the third direction DR3. The partition wall BM may provide a space for forming a first light conversion layer QDL1, a second light conversion layer QDL2, and a light transmission layer TPL. The partition wall BM may be formed of an organic insulating material, such as an acrylic resin, epoxy resin, phenolic resin, polyamide resin, polyimide resin, or the like. In other embodiments, the first photoconversion layer QDL1, the second photoconversion layer QDL2, and the light transmission layer TPL may be omitted.

The partition wall BM may have a tapered shape with a narrower width towards the top but is not limited thereto.

In one or more embodiments, the partition wall BM is formed as a single layer but is not limited thereto. For example, the partition wall BM may be formed in two layers to provide sufficient space for the first light conversion layer QDL1, the second light conversion layer QDL2, and the light transmission layer TPL to be formed.

The partition wall BM may include a light-blocking material as described above. For example, the partition wall BM may include an inorganic black pigment, such as carbon black or an organic black pigment.

A second reflective film RF may be arranged inside the space formed by the partition wall BM. The second reflective film RF may be arranged on a side surface of the partition wall BM.

The second reflective film RF serves to reflect light traveling in a lateral direction from the first light conversion layer QDL1, the second light conversion layer QDL2, and the light transmission layer TPL.

The second reflective film RF may include a metal material having a high light reflectivity. For example, the second reflective film RF may include aluminum or silver or may include an alloy thereof. Further, the second reflective film RF may be formed as a double structure of organic films having different refractive indices. In this case, an organic film having a lower refractive index may be arranged closer to the light-emitting element LE and an organic film having a higher refractive index may be arranged farther away from the light-emitting element LE.

In the first sub-pixel SPX1, a first light conversion layer QDL1 may be arranged between the partition walls BM and the partition walls BM, in the second sub-pixel SPX2, a second light conversion layer QDL2 may be arranged between the partition walls BM and the partition walls BM, and in the third sub-pixel SPX3, a light transmission layer TPL may be arranged between the partition walls BM and the partition walls BM.

The first light conversion layer QDL1 may convert a portion of the third light (light in the blue wavelength band) incident from the light-emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light-emitting element LE into first light (light in the red wavelength band).

The second light conversion layer QDL2 may convert a portion of the third light (light in the blue wavelength band) incident from the light-emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light-emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The capping layer CAP may be arranged on the partition wall BM, the first light conversion layer QDL1, the second light conversion layer QDL2, and the light transmission layer TPL.

The capping layer CAP may be formed of an inorganic film, such as silicon nitride (SiNₓ), silicon oxide nitride (SiON), silicon oxide (SiOₓ), titanium oxide (TiOₓ), or aluminum oxide (AlOₓ). The first light conversion layer QDL1, the second light conversion layer QDL2, and the light transmission layer TPL may be encapsulated by the capping layer CAP.

A fourth organic film 213 may be arranged on the capping layer CAP. A plurality of color filters CF1, CF2, and CF3 may be arranged on the fourth organic film 213. The plurality of color filters CF1, CF2, and CF3 may include first color filters CF1, second color filters CF2, and third color filters CF3.

The first color filter CF1 arranged in the first sub-pixel SPX1 may transmit the first light (light in a red wavelength band) and may absorb or block the third light (light in a blue wavelength band). Therefore, the first color filter CF1 may transmit the first light (light in a red wavelength band) converted by the first light conversion layer QDL1 among the third light (light in a blue wavelength band) emitted from the light-emitting element LE and absorb or block the third light (light in a blue wavelength band) not converted by the first light conversion layer QDL1. Therefore, the first sub-pixel SPX1 may emit the first light (light in a red wavelength band).

The second color filter CF2 arranged in the second sub-pixel SPX2 may transmit the second light (light in the green wavelength band) and absorb or block the third light (light in the blue wavelength band). Therefore, the second color filter CF2 may transmit the second light (light in the green wavelength band) converted by the first light conversion layer QDL1 among the third light (light in the blue wavelength band) emitted from the light-emitting element LE and absorb or block the third light (light in the blue wavelength band) not converted by the first light conversion layer QDL1. Therefore, the second sub-pixel SPX2 may emit the second light (light in the green wavelength band).

The third color filter CF3 arranged in the third sub-pixel SPX3 may transmit the third light (light in the blue wavelength band). Therefore, the third color filter CF3 may transmit the third light (light of a blue wavelength band) emitted from the light-emitting element LE passing through the light transmission layer TPL. Therefore, the third sub-pixel SPX3 may emit the third light (light of a blue wavelength band).

The first color filter CF1, the second color filter CF2, and the third color filter CF3 overlapping in the third direction DR3 may overlap the partition wall BM in the third direction DR3.

In one or more other embodiments, the first color filter CF1, the second color filter CF2, and the third color filter CF3 may be omitted.

A fifth organic film 214 for planarization can be arranged on the plurality of color filters CF1, CF2, and CF3.

The fourth organic film 213 and the fifth organic film 214 may be formed from an acrylic resin, an epoxy resin, a phenolic resin, a polyamide resin, a polyimide resin, or the like.

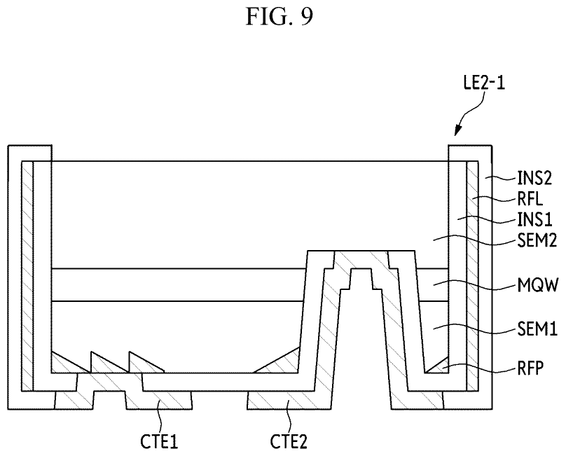

FIG. 9 is an enlarged view of another example of a 2-1 light-emitting element, which is a second-type light-emitting element of FIG. 7.

FIG. 9 is different from the embodiment of FIG. 8 in that the first protective film INS1, the first reflective film RFL, and the second protective film INS2 are not arranged on the upper portion of the light-emitting element LE. In FIG. 9, descriptions that overlap with the embodiment of FIG. 8 will be omitted, and differences from the embodiment of FIG. 7 will be mainly described.

The first protective film INS1 may surround a portion of the side and bottom surface of the semiconductor layer SEM1, MQW, and SEM2. The first reflective film RFL may surround a side of the light-emitting element LE outside the first protective film INS1. The second protective film INS2 may surround a side of the light-emitting element LE on the first reflective film RFL. The second protective film INS2 may cover an end of the first reflective film RFL adjacent to the contact electrodes CTE1 and CTE2 to reduce or prevent contact between one end of the first reflective film RFL and the contact electrodes CTE1 and CTE2.

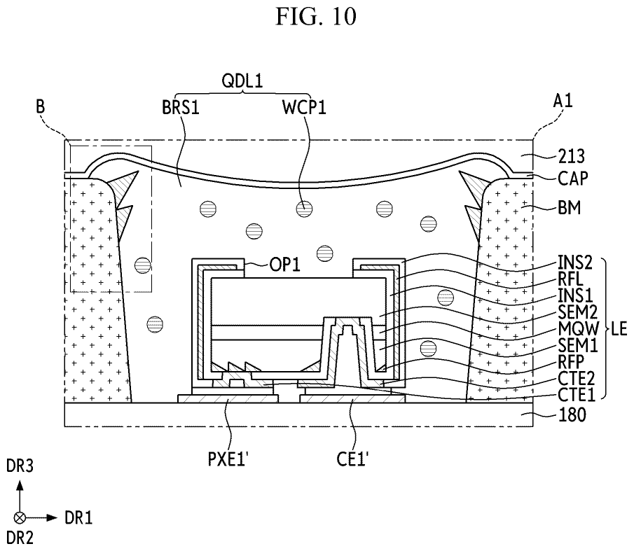

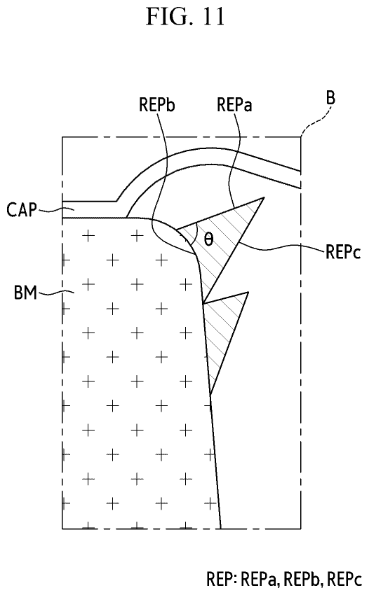

FIG. 10 is an enlarged view of area A1 of FIG. 6 according to one or more other embodiments. FIG. 11 is an enlarged view of area B of FIG. 10.

FIG. 10 is different from the embodiment of FIG. 7 in that it has a second reflective pattern REP on the bulkhead. In FIG. 10, descriptions that overlap with the embodiment of FIG. 7 will be omitted, and differences from the embodiment of FIG. 7 will be mainly described.

For convenience of explanation, the reflective pattern included in the light-emitting element LE is referred to as the first reflective pattern RFP.

Referring to FIG. 10, the second reflective pattern REP may be formed in one or more triangular mountain shapes (e.g., triangular in a cross section) on one side adjacent to the upper portion of the partition wall BM. The cross-section of the second reflective pattern REP may be formed in at least one triangular shape among a right triangle, an equilateral triangle, or an isosceles triangle.

Each triangular mountain of the second reflective pattern REP includes an inclined surface (e.g., a first surface) REPa formed by protruding at a corresponding angle from one side of the partition wall BM, and a side surface (e.g., a second surface) REPb that contacts (e.g., that is entirely in contact with) one side of the partition wall BM. The second reflective pattern REP includes a hypotenuse (e.g., a third surface) REPc formed along an angle of a tip formed by an inclined surface REPa and a side surface REPb. That is, the hypotenuse REPc may extend from an end of the inclined surface REPa to an end of the side surface REPb. The inclined surface REPa may be positioned higher than the hypotenuse REPc, and the hypotenuse REPc may be arranged to face the light-emitting element LE. The opening defined by the partition wall BM may be narrowed by the inclined surface REPa. The angle θ formed by the inclined surface REPa and the side surface REPb may be about 90 degrees or more.

The partition wall BM may be formed higher than the light-emitting element LE2-1, and the second reflective pattern REP may be arranged higher than the light-emitting element LE2-1. For example, the partition wall BM may be about twice or more greater than the height of the light-emitting element LE2-1. The light-emitting element LE2-1 may be about 5 μm or less, and the partition wall BM may be about 10 μm or more. The second reflective pattern REP may be arranged between about 5 μm and about 10 μm of the partition wall BM.

The second reflective pattern REP may be formed of a metal material having a high reflectivity, such as aluminum (Al), such as a reflective film but is not limited thereto.

The first reflective pattern RFP and the second reflective pattern REP may control the path of light emitted or reflected from the light-emitting element LE2-1 to limit the light emission area. Therefore, when the display device adopts the first reflective pattern RFP and the second reflective pattern REP, an effective narrow viewing angle mode may be provided.

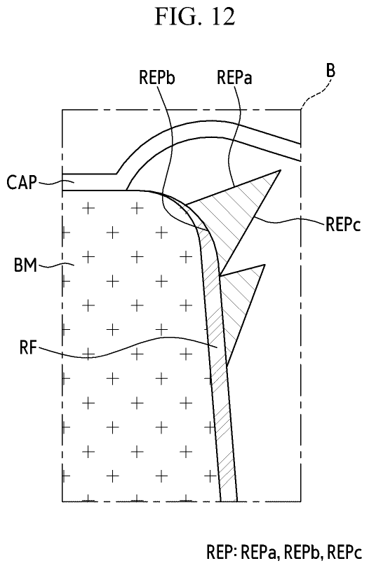

FIG. 12 is an enlarged view of area B of FIG. 10 according to one or more other embodiments.

FIG. 12 is different from the embodiment of FIG. 10 in that it has a second reflective film RF on the outside of the partition wall BM. In FIG. 12, descriptions that overlap with the embodiment of FIG. 10 will be omitted, and differences from the embodiment of FIG. 10 will be mainly described.

Referring to FIG. 12, a second reflective film RF may be arranged inside a space formed by the partition wall BM. The second reflective film RF may be arranged on a side surface of the partition wall BM.

The second reflective film RF serves to reflect light traveling in a side direction in the first light conversion layer QDL1, the second light conversion layer QDL2, and the light transmission layer TPL.

The second reflective film RF may include a metal material having a high light reflectivity. For example, the second reflective film RF may include aluminum or silver or may include an alloy thereof.

The second reflective pattern REP may be formed in one or more triangular mountain shapes on one side adjacent to the upper portion of the partition wall BM on the outside of the second reflective film RF.

The cross-section of the second reflective pattern REP may be formed in at least one triangular shape among a right triangle, an equilateral triangle, or an isosceles triangle.

Each triangular mountain of the second reflective pattern REP includes an inclined surface (e.g., first surface) REPa formed by protruding at a corresponding angle from one side of the partition wall BM, and a side surface (e.g., second side surface) REPb that contacts one side of the second reflective film RF. The second reflective pattern REP includes a hypotenuse (e.g., third surface) REPc formed along the angle of the tip portion formed by the inclined surface REPa and the side surface REPb (e.g., to extend from the inclined surface REPa to the side surface REPb). The inclined surface REPa may be positioned higher than the hypotenuse REPc, and the hypotenuse REPc may be arranged to face the light-emitting element LE. The opening defined by the partition wall BM may be narrowed by the inclined surface REPa. The angle θ between the inclined surface REPa and the side surface REPb may be greater than 90 degrees.

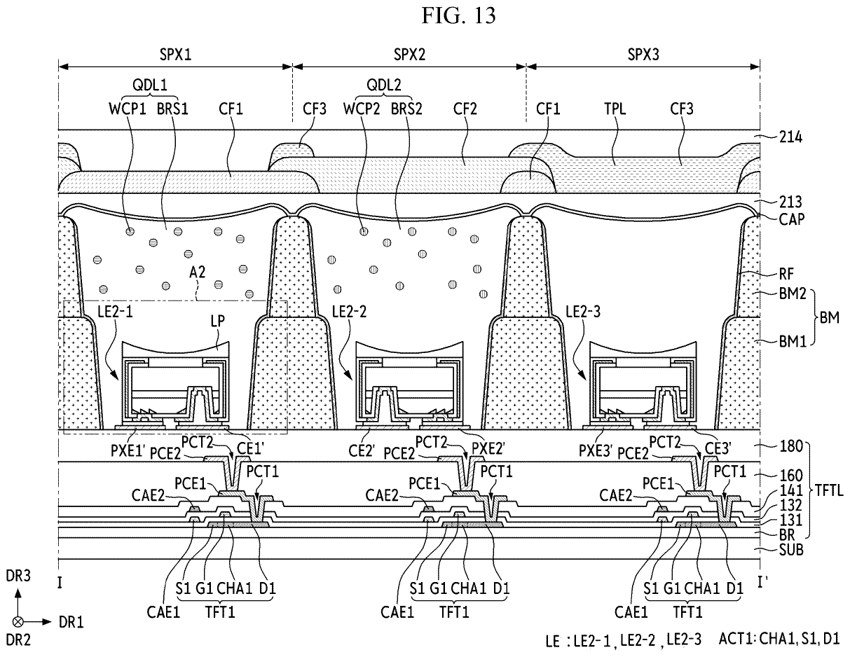

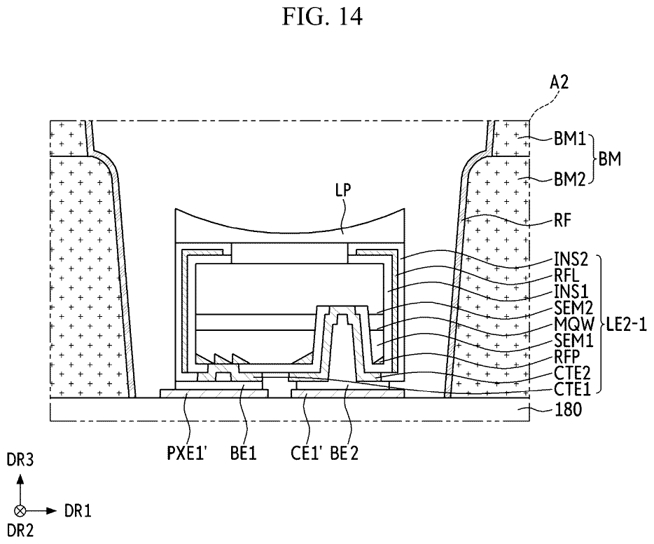

FIG. 13 is a cross-sectional view illustrating an example of a cross-section of a display panel taken along the line I-I′ of FIG. 5 according to one or more other embodiments. FIG. 14 is a cross-sectional view illustrating an example of the A1 area of FIG. 13 in detail.

FIGS. 13 and 14 differ in that the light-emitting element LE has an optical pattern on top of it and the the partition wall BM includes a first partition wall BM1 and a second partition wall BM2. In FIGS. 13 and 14, descriptions that overlap with the embodiments of FIGS. 6 and 7 will be omitted, and differences from the embodiments of FIGS. 6 and 7 will be mainly described.

An optical pattern LP is arranged on the upper portion of the light-emitting element LE and has a concave lens shape (e.g., that is concave downward). The optical pattern LP may contact at least a portion of the top surface of the light-emitting element LE. The width of the optical pattern LP may be wider than the width of the light-emitting element LE. The optical pattern LP may completely cover the light-emitting element LE, but is not limited thereto.

The optical pattern LP serves to refract light emitted from the upper portion of the light-emitting element LE. For example, the optical pattern LP may focus light to provide a narrow viewing angle.

The partition wall BM may include a first partition wall BM1 and a second partition wall BM2. The first partition wall BM1 may be arranged on the second planarization organic film 180, and the second partition wall BM2 may be arranged on the first partition wall BM1.

Each of the first partition wall BM1 and the second partition wall BM2 may have a constant tapered shape that decreases in width as it moves upward but is not limited thereto. A reflective layer RF may be arranged inside the space formed by the first partition wall BM1 and the second partition wall BM2. The reflective layer RF may be arranged on the side of the first partition wall BM1 and the second partition wall BM2.

A first light conversion layer QDL1, a second light conversion layer QDL2, and a light transmission layer TPL may be formed in the space formed by the first partition wall BM1 and the second partition wall BM2.

When the partition wall BM is formed in multiple layers, the first light conversion layer QDL1 and the second light conversion layer QDL2 may have sufficient space. Accordingly, it has the advantage that light conversion may be performed effectively the thickness of the display device may be increased.

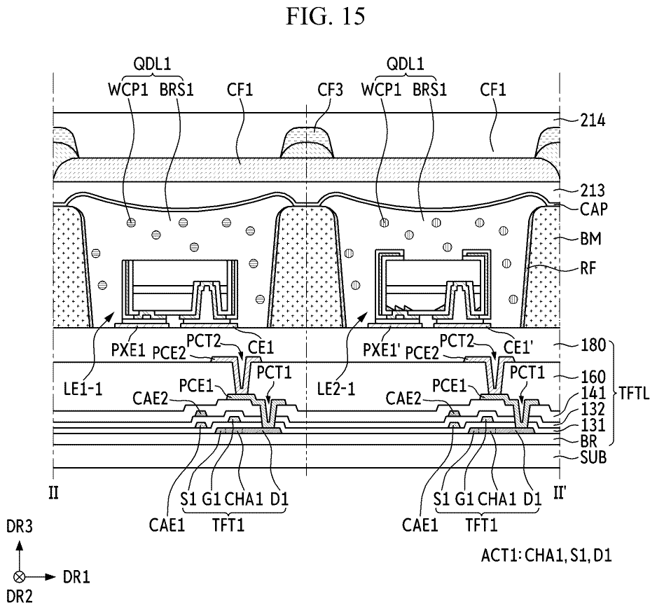

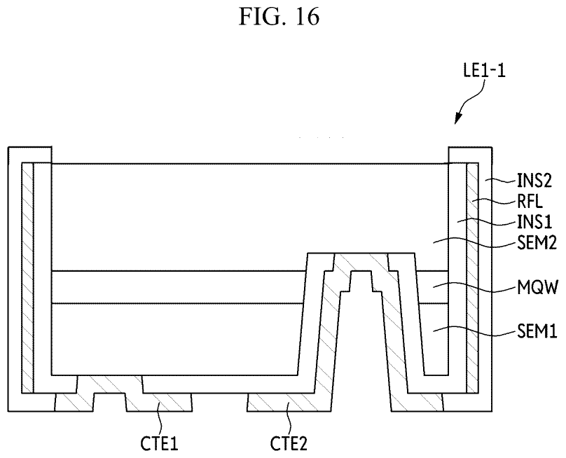

FIG. 15 is a cross-sectional view illustrating an example of the cross-section of the display panel corresponding to the line II-II′ of FIG. 5. FIG. 16 is a cross-sectional view illustrating an example of the first-type light-emitting element of FIG. 15 in detail.

Referring to FIG. 15 and FIG. 16 in consideration of FIG. 5, the first sub-pixel may include a 1-1 light-emitting element LE1-1 which is a first-type light-emitting element, and a 2-1 light-emitting element LE2-1 which is a second-type light-emitting element.

The substrate SUB may be made of an insulating material, such as glass or a polymer resin.

A thin film transistor layer TFTL may be arranged on the substrate SUB.

The thin film transistor layer TFTL may include a barrier film BR, a thin film transistor TFT1, a first gate-insulating film 131, a second gate-insulating film 132, an interlayer insulating film 141, a first planarization organic film 160, and a second planarization organic film 180. The thin film transistor layer TFTL has been described in detail with reference to FIG. 6, a redundant description will not be repeated.

Pixel electrodes PXE1 and PXE1′ and common electrodes CE1 and CE1′ may be arranged on the second planarization organic film 180.

A 1-1 light-emitting element LE1-1 or a 2-1 light-emitting element LE2-1 may be arranged on the pixel electrodes PXE1 and PXE1′ and the common electrodes CE1 and CE1′.

A detailed description of the 2-1 light-emitting element LE2-1 has been described in detail with reference to FIGS. 8 to 9, so the overlapping description will not be repeated.

Referring to FIG. 16, the 1-1 light-emitting element LE1-1 differs from the 2-1 light-emitting element LE2-1 of FIG. 9 in that it does not include a reflective pattern RFP.

The 2-1 light-emitting element LE2-1 has been described in detail with reference to FIGS. 8 and 9, so the overlapping description will not be repeated.

The transfer may be completed by selectively irradiating the second-type light-emitting element to each sub-pixel using a laser lift off (LLO) process to transfer light-emitting elements with different structures onto a substrate after selectively irradiating the first-type light-emitting element to each sub-pixel using the laser lift off (LLO) process. The transfer method is an example and is not limited thereto.

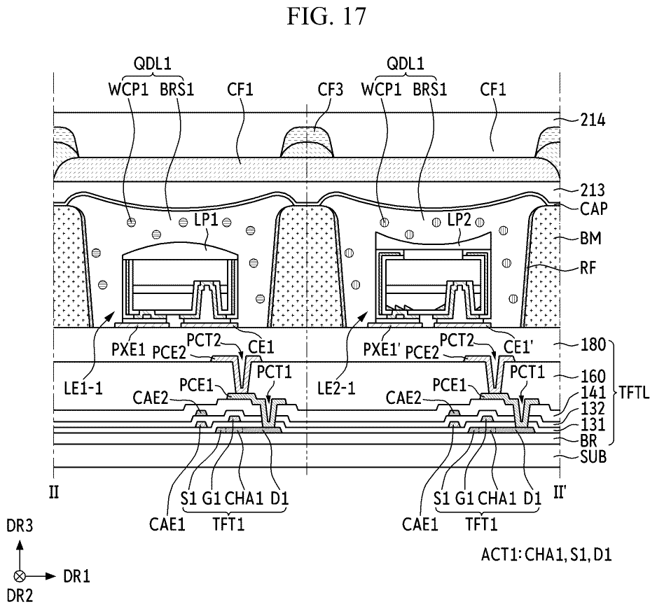

FIG. 17 is a cross-sectional view illustrating an example of the cross-section of the display panel corresponding to the line II-II′ of FIG. 5 according to one or more other embodiments.

Referring to FIG. 17, the first optical lens LP1 is arranged on the upper portion of the 1-1 light-emitting element LE1-1, and the second optical lens LP2 is arranged on the upper portion of the 2-1 light-emitting element LE2-1, which is different from the embodiment of FIG. 15. In FIG. 17, overlapping descriptions with the embodiment of FIG. 15 will be omitted, and differences from the embodiment of FIG. 15 will be mainly described.

Referring to FIG. 17, the first optical lens LP1 is arranged on the upper portion of the 1-1 light-emitting element LE1-1 in a convex lens shape that is convex upward. The width of the first optical lens LP1 may be wider than the width of the 1-1 light-emitting element LE1-1. The first optical lens LP1 may completely cover the 1-1 light-emitting element LE1-1. The first optical lens LP1 may diffuse light emitted from the 1-1 light-emitting element LE1-1, thereby contributing to the display device providing a wide viewing angle.

The second optical lens LP2 is arranged above the 2-1 light-emitting element LE2-1 in a concave lens shape (e.g., that is concave downward). The width of the second optical lens LP2 may be wider than the width of the 2-1 light-emitting element LE2-1. The second optical lens LP2 may completely cover the 2-1 light-emitting element LE2-1. The second optical lens LP2 may focus light emitted from the 2-1 light-emitting element LE2-1, thereby contributing to the display device providing a narrow viewing angle.

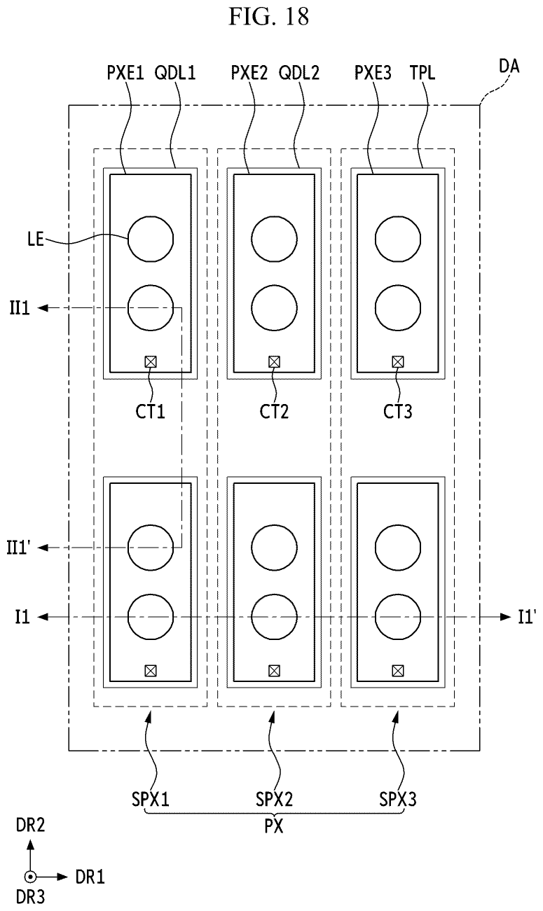

FIG. 18 is a layout diagram illustrating pixels of the display area according to one or more embodiments.

The embodiment of FIG. 18 differs from the embodiment of FIG. 5 in that the light-emitting elements LE overlap the pixel electrodes PXE1, PXE2, and PXE3 in each of the first sub-pixel SPX1, the second sub-pixel SPX2, and the third sub-pixel SPX3. In the embodiment of FIG. 18 the description overlapping with the embodiment of FIG. 5 is omitted.

Referring to FIG. 18, the first sub-pixel SPX1 includes a first pixel electrode PXE1, a plurality of first-type light-emitting elements LE1-1, a second-type light-emitting elements LE2-1, and a first light conversion layers QDL1 and QDL1′. The second sub-pixel SPX2 includes a second pixel electrode PXE2 and PXE2′, a plurality of first-type light-emitting elements LE1-2, a second light conversion layer QDL2 and QDL2′, a second pixel electrode PXE2′, a second-type light-emitting element LE2-2, and a second light conversion layer QDL2 and QDL2′. The third sub-pixel SPX3 includes a third pixel electrode PXE3 and PXE3′, a plurality of first-type light-emitting elements LE1-3, second-type light-emitting elements LE2-3, and a light transmission layer (or third light conversion layer) TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the sub-pixel may be larger as the light conversion efficiency is lower.

Each of the pixel electrodes PXE1, PXE2, and PXE3 may be electrically connected to at least one transistor through the pixel connection hole CT1, CT2, and/or CT3. For example, each of the pixel electrodes PXE1, PXE2, and PXE3 may be electrically connected to the second electrode of the fourth transistor (T4 in FIG. 4) and the second electrode of the sixth transistor (T6 in FIG. 4) of the corresponding sub-pixel.

A plurality of light-emitting elements LE may be arranged on each of the pixel electrodes PXE1, PXE2, and PXE3. The same number of light-emitting elements LE may be arranged on each of the pixel electrodes PXE1, PXE2, and PXE3. For example, two light-emitting elements may be arranged on each of the pixel electrodes PXE1, PXE2, and PXE3. The light-emitting elements arranged on one pixel electrode PXE1, PXE2, and PXE3 are light-emitting elements of the same type. For example, both light-emitting elements arranged on the first pixel electrode PXE1 may be first-type light-emitting elements LE1-1.

The first light conversion layer QDL1 may completely overlap the plurality of light-emitting elements LE of the first pixel electrode PXE1 and the first sub-pixel SPX1. The area of the first light conversion layer QDL1 may be larger than the area of the first pixel electrode PXE1. The first light conversion layer QDL1 may convert or shift the peak wavelength of incident light into light of another corresponding peak wavelength and emit the light. For example, the first light conversion layer QDL1 may convert or shift third light emitted from the plurality of light-emitting elements LE of the first sub-pixel SPX1 into first light.

The second light conversion layer QDL2 may completely overlap with the second pixel electrode PXE2 and the plurality of light-emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another corresponding peak wavelength and emit it. For example, the second light conversion layer QDL2 may convert or shift third light emitted from the plurality of light-emitting elements LE of the second sub-pixel SPX2 into second light.

The light transmission layer TPL may completely overlap with the third pixel electrode PXE3 and the plurality of light-emitting elements LE of the third sub-pixel SPX3. The light transmission layer TPL may directly transmit the incident light. For example, the light transmission layer TPL may directly transmit third light emitted from a plurality of light-emitting elements LE of the third sub-pixel SPX3.

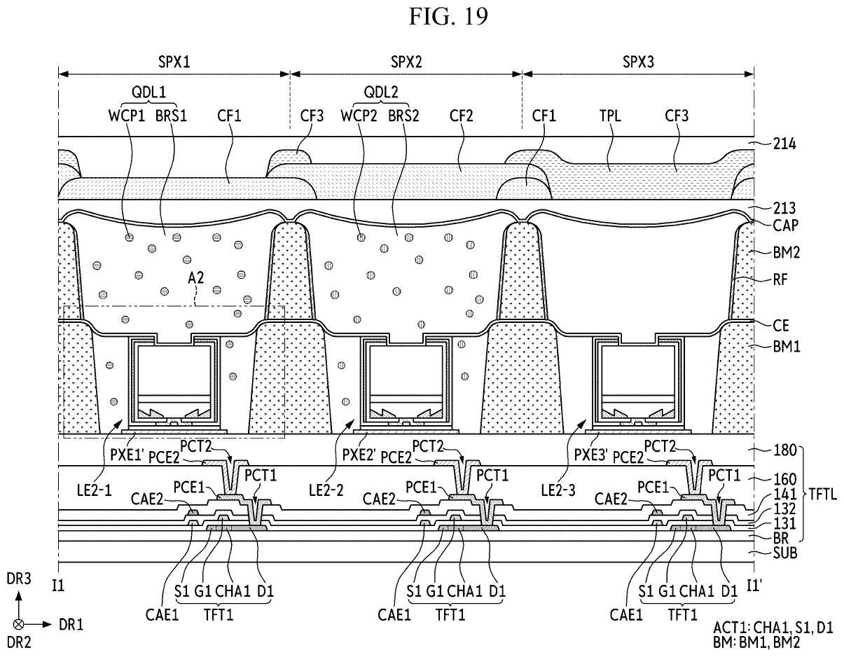

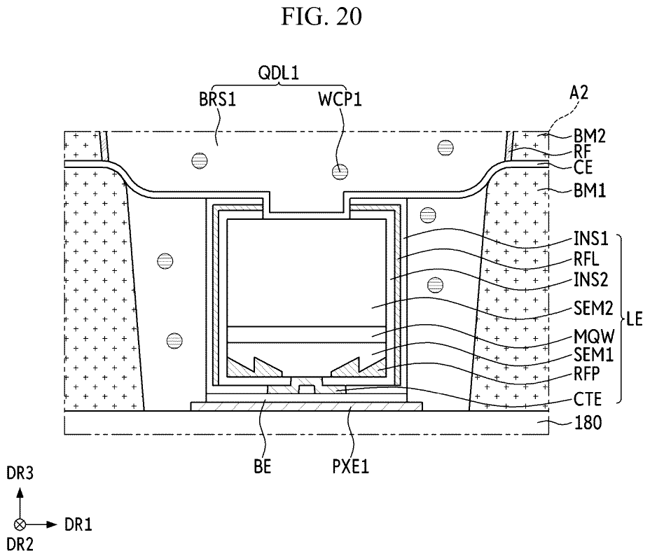

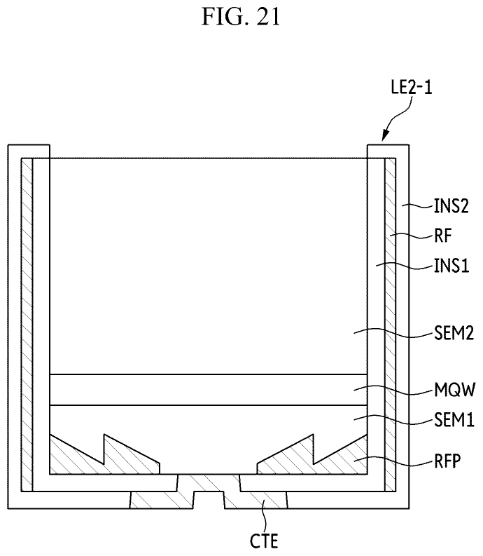

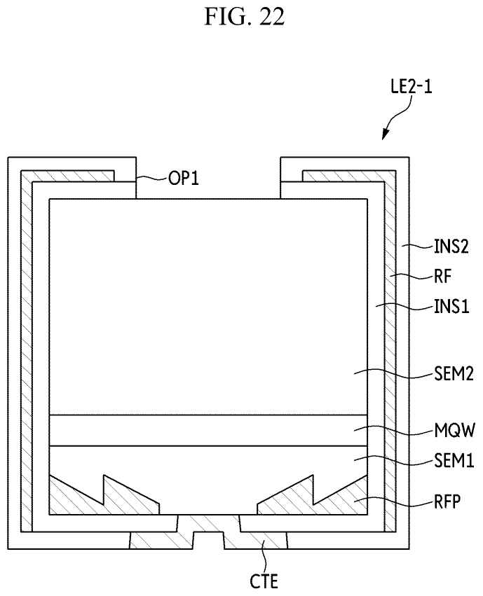

FIG. 19 is a cross-sectional view illustrating an example of the cross-section of the display panel corresponding to the line I1-I1′ of FIG. 18. FIG. 20 is a cross-sectional view illustrating an example of the A2 area of FIG. 19 in detail. FIG. 21 is an enlarged view of an example of the 2-1 light-emitting element, which is the second-type light-emitting element of FIG. 20. FIG. 22 is an enlarged view of another example of the 2-1 light-emitting element, which is the second-type light-emitting element of FIG. 20.

The embodiments of FIGS. 19 and 20 differ from the embodiments of FIGS. 6 and 7 in that each of the plurality of light-emitting elements LE is a vertical type micro LED extending in the third direction DR3. The vertical type micro LED refers to an LED having a structure in which a first semiconductor layer SEM1, an active layer MQW, and a second semiconductor layer SEM2 are sequentially arranged in the third direction DR3, which is a vertical direction.

In the embodiments of FIGS. 19 and 20, descriptions that overlap with those of the embodiments of FIGS. 6 and 7 will not be repeated.

Referring to FIGS. 19 and 20, a pixel electrode layer may be arranged on a second planarization organic film 180. The pixel electrode layer may include a first pixel electrode PXE1′, a second pixel electrode PXE2′, and a third pixel electrode PXE3′.

In one or more embodiments, a reflective layer may be arranged on the top surface of the first pixel electrode PXE1′, the second pixel electrode PXE2′, and the third pixel electrode PXE3′.

The reflective layer may reflect light traveling downward from the second-type light-emitting element LE2-1, LE2-2, and LE2-3 and emit light to the top surface of the second-type light-emitting element LE2-1, LE2-2, and LE2-3. Therefore, because the light loss of the second-type light-emitting element LE2-1, LE2-2, and LE2-3 may be reduced, the light efficiency of the second-type light-emitting element LE2-1, LE2-2, and LE2-3 may be increased.

The second-type light-emitting element LE2-1, LE2-2, and LE2-3 is arranged on the first pixel electrode PXE1′, the second pixel electrode PXE2′, and the third pixel electrode PXE3′.

Each of the plurality of second-type light-emitting elements LE2-1, LE2-2, and LE2-3 may have a length in the first direction DR1, a length in the second direction DR2, and a length in the third direction DR3 of several to several hundred μm, respectively. For example, each of the plurality of second-type light-emitting elements LE2-1, LE2-2, and LE2-3 may have a length in the first direction DR1, a length in the second direction DR2, and a length in the third direction DR3 of approximately 100 μm or less, respectively.

Referring to FIG. 21, the second-type light-emitting elements LE2-1, LE2-2, and LE2-3 may include a conductive layer E1, a first semiconductor layer SEM1, an active layer MQW, a second semiconductor layer SEM2, a contact electrode CTE, a first protective film INS1, a first reflective layer RFL, and a second protective film INS2.

The first protective film INS1 may be a film for protecting the bottom surface and the side surface of the light-emitting element LE and reducing or preventing contact between the first reflective film RFL and the semiconductor layers. Therefore, the first protective film INS1 may be formed of an inorganic film, such as an insulating film of silicon nitride (SiNₓ), silicon oxide nitride (SiON), silicon oxide (SiOₓ), titanium oxide (TiOₓ), or aluminum oxide (AlOₓ).

The protective film (e.g., the first protective film INS1 and/or the second protective film INS2) may be formed of an inorganic film, such as silicon nitride (SiNₓ), silicon oxide nitride (SiON), silicon oxide (SiOₓ), titanium oxide (TiOₓ), or aluminum oxide (AlOₓ).

The protective film has one or more openings for electrically connecting the first semiconductor layer SEM1 and the contact electrode CTE. In one or more embodiments, the first protective film INS1 includes one opening. The contact electrode CTE may be arranged on the first protective film INS1. Each of the plurality of contact electrodes CTE may be arranged between the pixel electrodes PXE1, PXE2, and PXE3 and the first protective film INS1. The contact electrodes CTE may be connected to the first semiconductor layer SME1 that is exposed and not covered by the first protective film INS1.

The contact electrodes CTE may include one of molybdenum (Mo), aluminum (Al), chromium (Cr), gold (Au), titanium (Ti), nickel (Ni), neodymium (Nd), or copper (Cu). For example, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The first reflective film RFL may surround the side surface of the light-emitting element LE on the first protective film INS1. The first reflective film RFL may not be arranged on the light-emitting element LE but is not limited thereto.

The second protective film INS2 reduces or prevents electrical connection between the first reflective film RFL and other components and serves to protect the first reflective film RFL. The second protective film INS2 covers the side surface and both ends of the light-emitting element LE on the outer surface of the first reflective film RFL to protect the first reflective film RFL. Therefore, the first reflective film RFL is not electrically connected to the semiconductor layer of the light-emitting element LE and the contact electrodes CTE1 and CTE2 by the second protective film INS2.

In one or more other embodiments, as shown in FIG. 22, the first reflective film RFL may surround the side surface of the light-emitting element LE and may cover a portion of the top surface of the light-emitting element LE. The first reflective film RFL may have an opening that overlaps with the first opening OP1 defined by the first protective film INS1. Therefore, the first reflective film RFL may be arranged on the top surface of the light-emitting element LE except for the first opening OP1. The top surface of the second semiconductor layer SEM2 may still be exposed by the first opening OP1. The first opening OP1 includes the center of the light-emitting element LE and may be arranged in the center area of the top surface of the light-emitting element LE but is not limited thereto.

As the opening of the first reflective film RFL becomes narrower, the straightness of the light-emitting element LE may increase. However, because the light emission efficiency may decrease as the opening of the first reflective film RFL becomes narrower, the area of the opening OP1 should be designed in consideration of the straightness and light emission efficiency of the light-emitting element LE.

The common electrode CE may be arranged on the top surface of each of the plurality of second-type light-emitting elements LE2. For example, the common electrode CE may be electrically connected to the second semiconductor layer SME2 of the second-type light-emitting element LE2. The common electrode CE may be a common layer formed commonly in the first sub-pixel SPX1, the second sub-pixel SPX2, and the third sub-pixel SPX3.

The common electrode CE may be made of a transparent conductive material (TCO), such as indium tin oxide (ITO) and indium zinc oxide (IZO) that can transmit light.

The pixel electrodes PXE1, PXE2, and PXE3 may be referred to as an anode electrode or a first electrode, and the common electrode CE may be referred to as a cathode electrode or a second electrode.

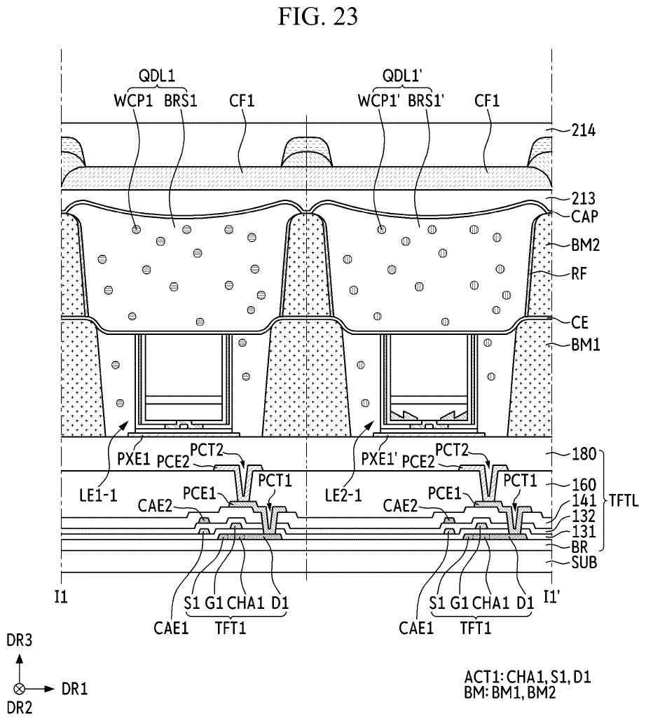

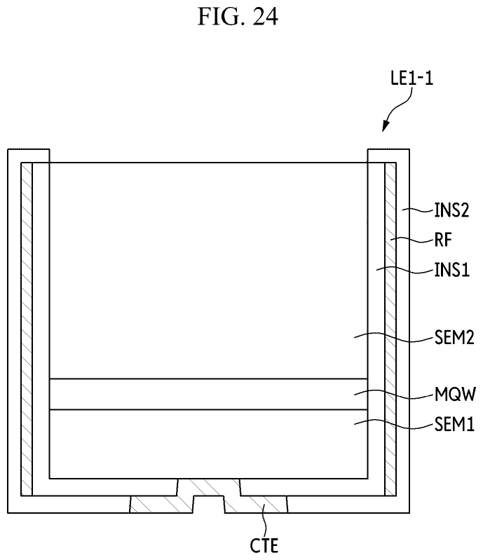

FIG. 23 is a cross-sectional view illustrating an example of a cross-section of a display panel taken along the line II1-II1′ of FIG. 18 according to one or more other embodiments. FIG. 24 is a cross-sectional view illustrating in detail an example of the first-type light-emitting element of FIG. 23.

Referring to FIG. 23 and FIG. 24 in consideration of FIG. 18, the first sub-pixel SPX1 may include a 1-1 light-emitting element LE1-1 as a first-type light-emitting element, and a 2-1 light-emitting element LE2-1 as a second-type light-emitting element.

The first-type transistor of the first sub-pixel SPX1 may be controlled to be driven by the seventh transistor T7 in FIG. 4, and the second-type transistor may be controlled to be driven by the ninth transistor T9 in FIG. 4.

The substrate SUB may be made of an insulating material, such as glass or polymer resin.

A thin film transistor layer TFTL may be arranged on the substrate SUB.

The thin film transistor layer TFTL may include a barrier film BR, a thin film transistor TFT1, a first gate-insulating film 131, a second gate-insulating film 132, a slating film 141, a first planarization organic film 160, and a second planarization organic film 180. The thin film transistor layer TFTL has been described in detail with reference to FIG. 6, so the redundant description will not be repeated.

The pixel electrodes PXE1 and PXE1′ may be arranged on the second planarization organic film 180.

A 1-1 light-emitting element LE1-1 or a 2-1 light-emitting element LE2-1 may be arranged on the pixel electrodes PXE1 and PXE1′.

A detailed description of the 2-1 light-emitting element LE2-1 has been described in detail with reference to FIGS. 21 and 22, so the redundant description will not be repeated.

Referring to FIG. 24, the 1-1 light-emitting element LE1-1 differs from the 2-1 light-emitting element LE2-1 of FIG. 21 in that it does not include a reflective pattern RFP.

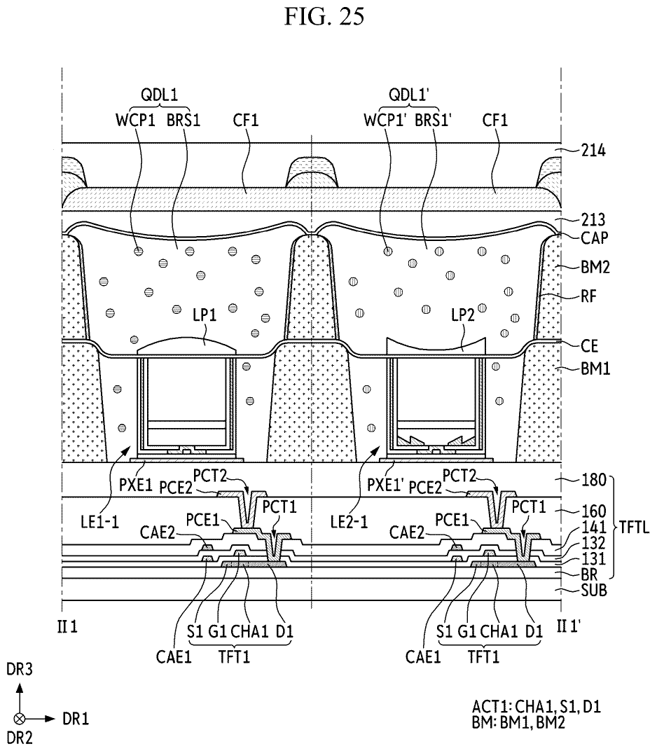

FIG. 25 is a cross-sectional view illustrating an example of a cross-section of a display panel taken along the line II1-II1′ of FIG. 18 according to one or more other embodiments.

Referring to FIG. 25, the first optical lens LP1 is arranged on the upper portion of the 1-1 light-emitting element LE1-1, and the second optical lens LP2 is arranged on the upper portion of the 2-1 light-emitting element LE2-1, which is different from the embodiment of FIG. 15. In FIG. 25, overlapping descriptions with the embodiment of FIG. 23 will be omitted, and differences from the embodiment of FIG. 23 will be mainly described.

Referring to FIG. 25, the first optical lens LP1 is arranged on the upper portion of the 1-1 light-emitting element LE1-1 in a convex lens shape that is convex upward. The width of the first optical lens LP1 may be wider than the width of the 1-1 light-emitting element LE1-1. The first optical lens LP1 may completely cover the 1-1 light-emitting element LE1-1. The first optical lens LP1 may diffuse light emitted from the 1-1 light-emitting element LE1-1, thereby contributing to the display device providing a wide viewing angle.

The second optical lens LP2 is arranged above the 2-1 light-emitting element LE2-1 in a concave lens shape (e.g., that is concave downward). The width of the second optical lens LP2 may be wider than the width of the 2-1 light-emitting element LE2-1. The second optical lens LP2 may completely cover the 2-1 light-emitting element LE2-1. The second optical lens LP2 may focus light emitted from the 2-1 light-emitting element LE2-1, thereby contributing to the display device providing a narrow viewing angle.

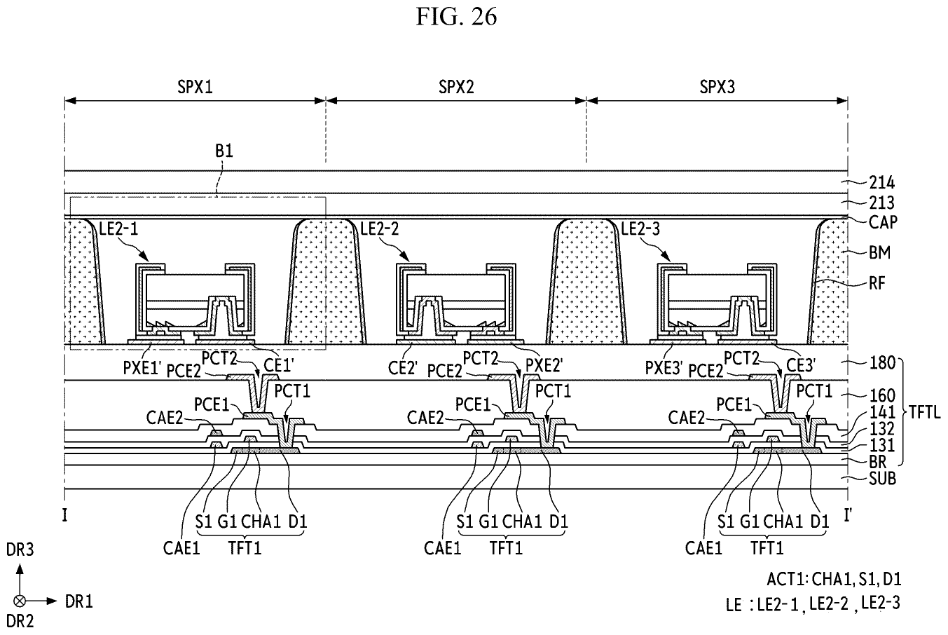

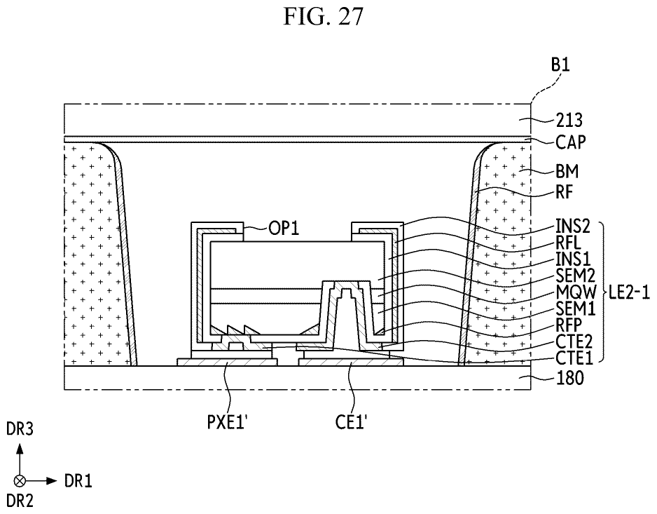

FIG. 26 is a cross-sectional view cut along the line I-I′ of FIG. 5 according to one or more other embodiments. FIG. 27 is an enlarged view of area B1 of FIG. 26.

FIGS. 26 and 27 differ from the embodiments of FIGS. 6 and 7 in that the first light conversion layer QDL1, the second light conversion layer QDL2, the light transmission layer TPL, and the plurality of color filters CF1, CF2, and CF3 are not arranged. In FIGS. 26 and 27, descriptions that overlap with the embodiments of FIGS. 6 and 7 will be omitted, and differences from the embodiments of FIGS. 6 and 7 will be mainly described.

Referring to FIGS. 26 and 27, a capping layer CAP may be arranged on a light-emitting element LE and a partition wall BM.

The light-emitting element LE and the partition wall BM may be enclosed by the capping layer CAP.

A fourth organic film 213 may be arranged on the capping layer CAP.

A fifth organic film 214 may be arranged on the fourth organic film 213. Either the fourth organic film 213 or the fifth organic film 214 may be omitted.

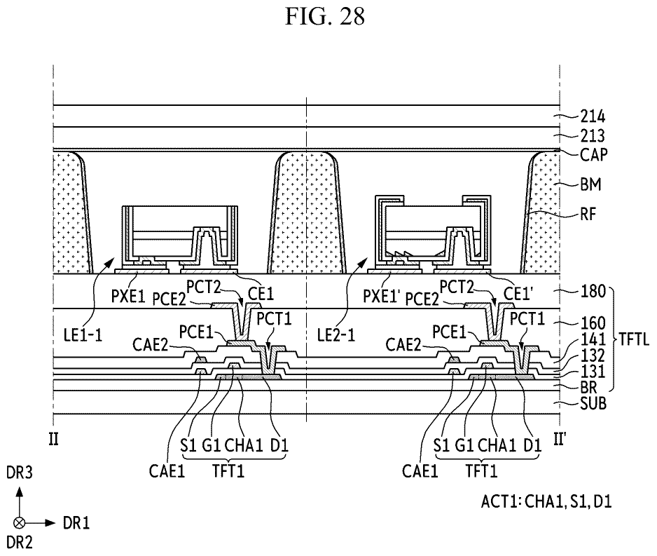

FIG. 28 is a cross-sectional view illustrating an example of a cross-section of a display panel taken along the line II-II′ of FIG. 5 according to one or more other embodiments.

FIG. 28 is different from the embodiment of FIG. 15 in that the first light conversion layer QDL1, the second light conversion layer QDL2, the light transmission layer TPL, and the plurality of color filters CF1, CF2, and CF3 are not arranged. In FIG. 28, descriptions that overlap with the embodiment of FIG. 15 will be omitted, and differences from the embodiment of FIG. 15 will be mainly described.

Referring to FIG. 28 in consideration of FIG. 26, the light-emitting element LE and the partition wall BM may be enclosed by the capping layer CAP.

A fourth organic film 213 may be arranged on the capping layer CAP.

A fifth organic film 214 may be arranged on the fourth organic film 213. Either the fourth organic film 213 or the fifth organic film 214 may be omitted.

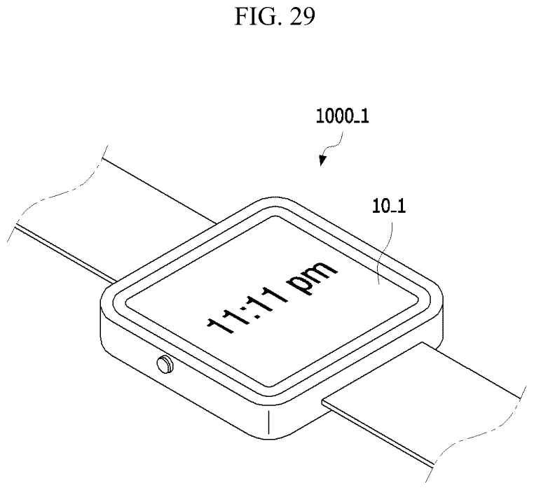

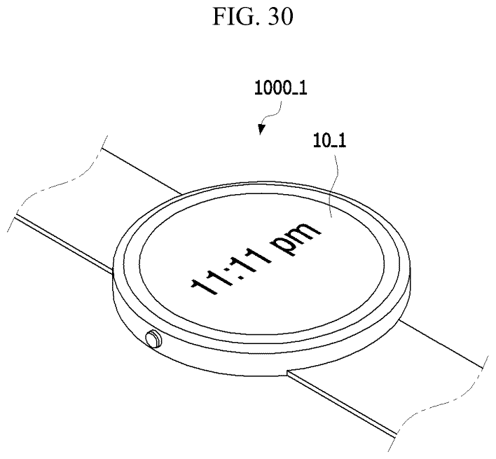

FIGS. 29 and 30 are drawings illustrating a smart watch including a display device according to one or more embodiments.

Referring to FIGS. 29 and 30, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

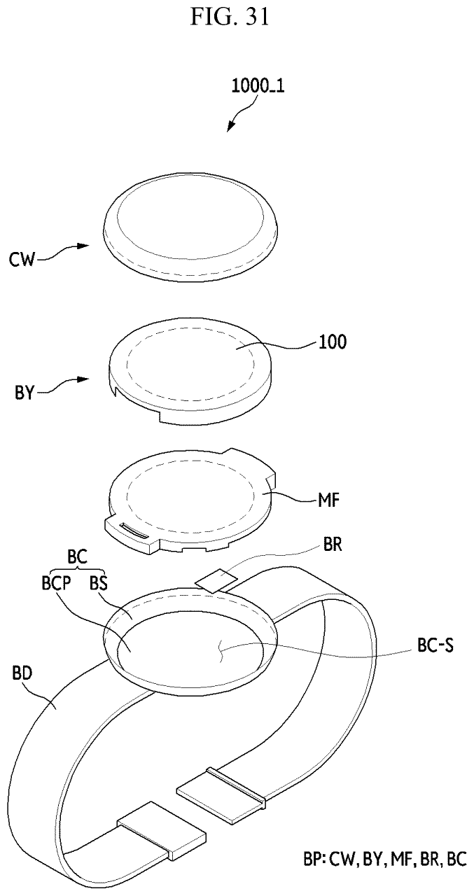

FIG. 31 is an exploded perspective view of a smart watch including a display device according to one or more embodiments.

Referring to FIG. 31, the smart watch 1000_1 may include a main body unit BP and a wearable portion BD.

The main body unit BP may include a display panel 100 on which an image is displayed, a cover window CW located on the display panel 100, a bottom cover BC located under the display panel 100, a middle frame MF located between the cover window CW and the bottom cover BC, and a battery BR located between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 100 to protect the display panel 100 and to transmit light emitted from the display panel 100. As described above, the cover window CW may include a light-blocking portion to block a portion of the light emitted from the display panel 100. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon, such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 100. The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a curvature (e.g., predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, or a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, or a bracelet.

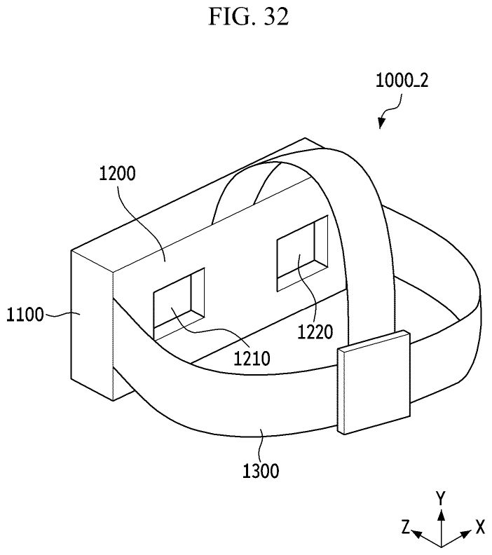

FIG. 32 is example views of a virtual reality (VR) device including a display device according to one or more embodiments.

Referring to FIG. 32, a head-mounted display device 1000_2 according to one or more embodiments include a display device housing 1100, a housing cover 1200, a first eyepiece 1210, a second eyepiece 1220, and head-mounted band 1300.

The display device housing 1100 houses a display device. a head-mounted display device 1000_2 according to one or more embodiments further include a first optical member located between a corresponding first display device and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are located separately in FIG. 30, the present disclosure is not limited thereto. The first eyepiece 1210 and the second eyepiece 1220 may also be combined into one.

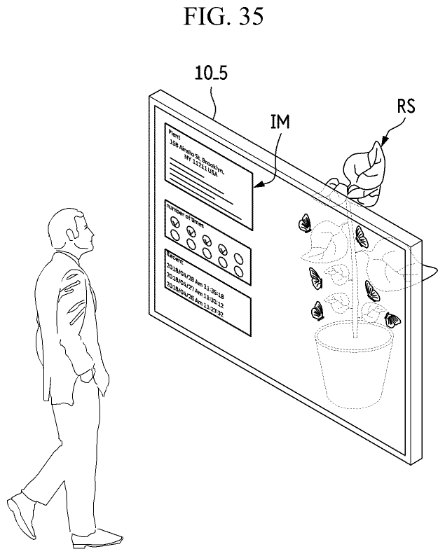

The head-mounted band 1300 fixes the display device housing 1100 to a user's head so that the first eyepiece 1210 and the second eyepiece 1220 of the housing cover 1200 are kept placed on the user's left and right eyes, respectively. When the housing cover 1200 is implemented to be lightweight and small, the head-mounted display device 1000_2 may include an eyeglass frame as illustrated in FIG. 35 instead of the head-mounted band 1300.

The display device housing 1100 houses display device. In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

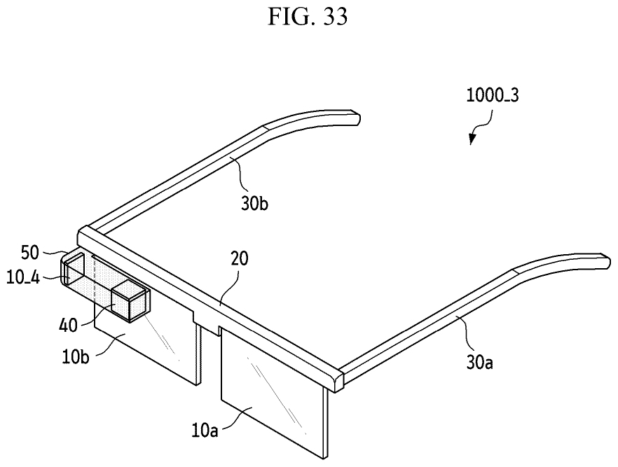

FIG. 33 is an example view of a VR device including a display device according to one or more embodiments. FIG. 31 illustrates a VR device 1000_3 to which a display device 10_4 according to one or more embodiments has been applied.

Referring to FIG. 33, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 33, a case where the VR device 1000_3 is a glasses-type display device including the eyeglass frame legs 30a and 30b is illustrated as an example. That is, the VR device 1000_3 according to the embodiment is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is located at a right end of the support frame 20 in FIG. 33, the present disclosure is not limited thereto. For example, the display device housing 50 may also be located at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

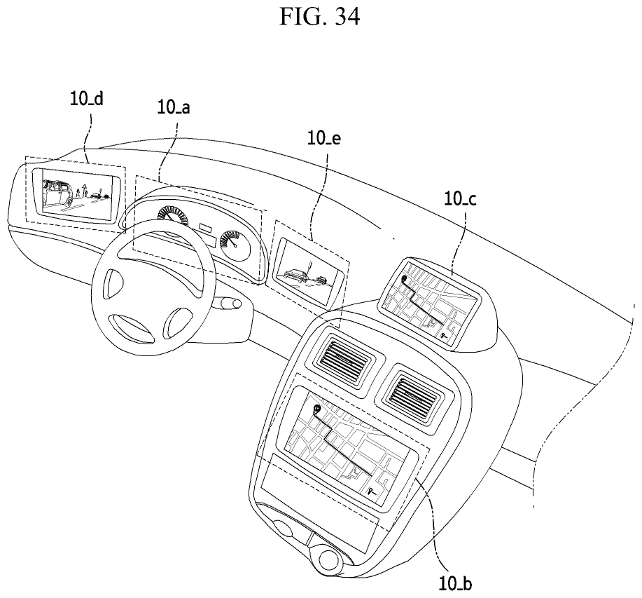

FIG. 34 is an example view illustrating a vehicle instrument cluster and center fascia including display devices according to one or more embodiments. FIG. 32 illustrates a vehicle to which display devices 10_a through 10_e according to one or more embodiments have been applied.

Referring to FIG. 34, the display devices 10_a through 10_c according to the embodiment may be applied to an instrument cluster of the vehicle, a center fascia of the vehicle, or a center information display (CID) located on a dashboard of the vehicle. In addition, the display devices 10_d and 10_e according to the embodiment may be applied to room mirror displays that replace side mirrors of the vehicle.

FIG. 35 is an example view of a transparent display device including a display device according to one or more embodiments.

Referring to FIG. 35, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a transistor layer comprising a first transistor and a second transistor; and
a sub-pixel comprising a first-type light-emitting element configured to be driven by the first transistor, and a second-type light-emitting element configured to be driven by the second transistor and comprising a first reflective pattern having a triangular shape at a lower portion of the second-type light-emitting element and comprising a reflective surface inclined toward a center of the lower portion.

2. The display device of claim 1, wherein the first reflective pattern is provided in plural, and
wherein the first reflective patterns are on respective sides of the second-type light-emitting element such that the reflective surfaces face each other.

3. The display device of claim 2, wherein the second-type light-emitting element comprises:
semiconductor layers;
a reflective film on side and top surfaces of the semiconductor layers and defining an opening;
a first protective film between the semiconductor layers and the reflective film; and
a second protective film on an outside of the reflective film.

4. The display device of claim 3, wherein the first reflective pattern is spaced from an area overlapping the opening.

5. The display device of claim 1, further comprising:
a partition wall on the transistor layer and surrounding the first-type light-emitting element and the second-type light-emitting element in plan view; and
at least one second reflective pattern having a triangular shape adjacent to an upper portion of the partition wall and surrounding the second-type light-emitting element in plan view.

6. The display device of claim 5, wherein the at least one second reflective pattern comprises a first surface protruding at an angle from the partition wall, a second surface entirely in contact with the partition wall, and a third surface below the first surface and extending from the first surface to the second surface.

7. The display device of claim 6, wherein the angle is about 90 degrees or more.

8. The display device of claim 5, wherein the second reflective pattern is at a level that is above the second-type light-emitting element.

9. The display device of claim 8, wherein the partition wall has a tapered shape that narrows in an upward direction.

10. The display device of claim 8, wherein the first reflective pattern and the second reflective pattern comprise at least one of aluminum or silver.

11. The display device of claim 1, further comprising a first optical pattern comprising a concave lens above the second-type light-emitting element.

12. The display device of claim 11, further comprising a second optical pattern comprising an upwardly convex lens above the first-type light-emitting element.

13. The display device of claim 1, wherein the first transistor is configured to operate in a wide viewing angle mode, and
wherein the second transistor is configured to operate in a narrow viewing angle mode.

14. The display device of claim 5, further comprising:
a wavelength conversion layer in a space defined by the partition wall; and
a capping layer, an overcoat layer, and a color filter layer sequentially ordered above the partition wall.

15. A display device comprising:
a substrate;
a transistor layer above the substrate;
a pixel electrode layer above the transistor layer;
a light-emitting element above the pixel electrode layer having triangular first reflective patterns at a lower portion of the light-emitting element and inclined toward a center of the light-emitting element; and
a partition wall surrounding the light-emitting element in plan view.

16. The display device of claim 15, wherein the light-emitting element comprises:
semiconductor layers;
a reflective film defining on side and top surfaces of the semiconductor layers and defining an opening spaced apart from the first reflective patterns in plan view;
a first protective film between the semiconductor layers and the reflective film; and
a second protective film on an outside of the reflective film.

17. The display device of claim 16, further comprising one or more triangular second reflective patterns on one side adjacent to an upper portion of the partition wall and surrounding the light-emitting element in plan view, and comprising a first surface protruding at an angle from the partition wall, a second surface entirely in contact with the one side of the partition wall, and a third surface below the first surface and extending from the first surface to the second surface.

18. The display device of claim 17, wherein the one or more triangular second reflective patterns are at a level above the light-emitting element.

19. The display device of claim 17, further comprising an optical pattern comprising a concave lens above the light-emitting element.

20. An electronic device comprising:
a display panel for displaying an image and comprising:
a substrate;
a transistor layer comprising a first transistor and a second transistor; and
a sub-pixel including a first-type light-emitting element configured to be driven by the first transistor, and a second-type light-emitting element configured to be driven by the second transistor and comprising a first reflective pattern having a triangular shape at a lower portion of the second-type light-emitting element and comprising a reflective surface inclined toward a center of one surface of the second-type light-emitting element.
